(19) United States
(12) Patent Application Publication
(10) Pub. No.: US 2026/0247579 A1
(43) Pub. Date: Aug. 20, 2026

(54) AUTOMATED COOLING REQUIREMENT DETERMINATION FOR COMPUTING ENVIRONMENTS

(71) Applicant: Nvidia Corporation, Santa Clara, CA (US)

(72) Inventors: Benjamin Goska, Portland, OR (US); Ryan Albright, Beaverton, OR (US); William Andrew Mecham, Elk Grove, CA (US); William Ryan Weese, Portland, OR (US); Aaron Carkin, Hillsboro, OR (US); Michael Thompson, Wilsonville, OR (US); Jordan Levy, Portland, OR (US)

(21) Appl. No.: 19/059,183

(22) Filed: Feb. 20, 2025

(51) Int. Cl. H05K 7/20; G06K 7/10

(52) U.S. Cl. CPC H05K 7/207; G06K 7/10009; H05K 7/2059; H05K 7/20654

(57) ABSTRACT

Approaches presented herein provide for automated management of operational systems, such as cooling and power systems, for a computing environment such as a data center. A secondary coolant distribution unit (CDU) can be connected to a cooling loop to allow for cutover from coolant flow from a primary CDU, which can allow for tasks such as coolant cleaning or replacement without having to power down the electronic components being cooled by the coolant flow. The cooling system can also be used to cure thermal interface materials (TIMs) by heating the flow of liquid through the cooling system to at least one target temperature over a period of time according to a curing profile. The electronic components can also have tags attached that allow for automatic detection and reading when installed in the electronic environment, which allows for automated detection and analysis of the needs of a set of components, as well as the automated adjustment of one or more operational systems to satisfy those needs with zero downtime of the impacted components.

### TECHNICAL FIELD

At least one embodiment pertains to managing operational systems used with deployments of electronic devices, and in particular to adjusting operational parameters of an environment such as a data center to control aspects of cooling, power, temperature control, and/or other such systems.

### BACKGROUND

As the capabilities of various electronic and heat-generating components—such as servers, network switches, and systems on chip—continue to increase, there is a corresponding need to more closely manage the operation of these devices to avoid issues with overheating or insufficient power. For example, there may be many electronic components in a data center, and each of these components may have specific requirements as to cooling, power, temperature, and other such operational aspects. In order to allow for proper operation of such a data center with zero downtime of operational components, it can be beneficial to detect any changes in requirements and make the appropriate adjustments. This can include, for example, adjusting a flow of cooling liquid in response to the addition or removal of a server in a rack. There may also be times when it is appropriate to clean or replace the cooling liquid in a cooling system. In prior approaches, these tasks were largely performed manually by a human, and often required powering down of at least some of the components. Such an approach is susceptible to human error and inconsistencies, and also may cause a data center to operate outside expected operational ranges for a period of time until a human identifies that a change is needed, and can then perform the appropriate change. Such aspects can impact the availability of resources in an environment such as a data center, and errors in operation can result in failures and additional maintenance, which can increase costs and decrease performance of the resources in that environment.

### BRIEF DESCRIPTION OF THE DRAWINGS

Various embodiments in accordance with the present disclosure will be described with reference to the drawings, in which:

FIGS. 1A-1B illustrate an exemplary data center cooling system subject to improvements described in at least one embodiment;

FIG. 2 illustrates server-level features associated with cold plates as liquid manifolds in computer hardware, according to at least one embodiment;

FIG. 3 illustrates rack-level features associated with cold plates as liquid manifolds in computer hardware, according to at least one embodiment;

FIG. 4 illustrates component-level features associated with cold plates as liquid manifolds in computer hardware, according to at least one embodiment;

FIG. 5 illustrates an example heat exchanger that is able to be connected to a server to provide for liquid cooling, according to at least one embodiment;

FIG. 6 illustrates a system allowing for cutover between a primary CDU and a secondary CDU, according to at least one embodiment;

FIG. 7 illustrates a system allowing for cutover between a primary CDU and a secondary CDU, where the secondary CDU can accept a biocide to clean the cooling system, according to at least one embodiment;

FIG. 8 illustrates a system allowing for cutover between a primary CDU and a secondary CDU to allow for replacement of cooling fluid in a cooling system, according to at least one embodiment;

FIG. 9 illustrates an example process for switching between coolant flow from a primary CDU and a secondary CDU, according to at least one embodiment;

FIGS. 10A and 10B illustrate views of a layer of thermal interface material (TIM) between a heat-generating component and a heat sink, according to at least one embodiment;

FIG. 11 illustrates an example configuration that allows for heating of the fluid in a cooling system to cure TIMs connected to a set of cold plates, according to at least one embodiment;

FIG. 12 illustrates an example system usable to heat the fluid in a cooling system to cure a TIM connected to a cold plate, according to at least one embodiment;

FIG. 13A illustrates an example process that can be performed to cure a set of thermal interface materials, according to at least one embodiment;

FIG. 13B illustrates an example process that can be performed to cure a set of thermal interface materials, according to at least one embodiment;

FIG. 14 illustrates an example configuration of tag readers associated with a rack manifold, according to at least one embodiment;

FIG. 15 illustrates a system that can be used to automatically adjust one or more operational parameters of a data center in response to detecting updated requirements, according to at least one embodiment;

FIG. 16 illustrates an example process that can be performed to automatically adjust one or more operational parameters of a computing environment in response to detecting updated requirements, according to at least one embodiment;

FIG. 17 illustrates components of a distributed computing system that can be used to receive and manage data, according to at least one embodiment;

FIG. 18 illustrates an example data center system, according to at least one embodiment;

FIG. 19 is a block diagram illustrating a computer system, according to at least one embodiment;

FIG. 20 is a block diagram illustrating a computer system with a parallel processing system, according to at least one embodiment;

FIG. 21 illustrates a computing system with a parallel processor, according to at least one embodiment;

FIG. 22 illustrates a computer system with a parallel processor, according to at least one embodiment;

FIG. 23 illustrates a computer system, according to at least one embodiment; and

FIG. 24 illustrates a computing system, according to at least one embodiment.

### DETAILED DESCRIPTION

In the following description, various embodiments will be described. For purposes of explanation, specific configurations, and details are set forth in order to provide a thorough understanding of the embodiments. However, it will also be apparent to one skilled in the art that the embodiments may be practiced without the specific details. Furthermore, well-known features may be omitted or simplified in order not to obscure the embodiment being described.

Approaches in accordance with various illustrative embodiments provide for the cooling of heat-generating electronic components, and in particular, to the use of liquid cooling in computer servers. Large Cooling Distribution Units (CDU) may be cooling many units, and the plumbing involved makes moving a server require either disconnecting, unpowering, or moving both the liquid cooling setup and the server together.

The transition to liquid cooling in server products has exposed shortcomings in conventional solutions that have historically been employed for thermal management. For example, there is the complexity associated with isolating or servicing individual servers within a liquid-cooled framework. Unlike air-cooled systems, where each unit can operate independently with minimal interference from neighboring units, liquid-cooled environments rely on centralized Cooling Distribution Units (CDUs) that service multiple servers simultaneously. This interconnected design creates challenges when maintenance or relocation of a single server is required. Technicians must disconnect and power down both the server and its associated cooling infrastructure, leading to increased downtime and operational disruptions. Moreover, the intricate plumbing involved in these systems may complicate attempts to move or replace servers without extensive preparation and coordination. In situations where immediate access or containment is necessary—such as during testing or troubleshooting—the inability to decouple a server from the broader cooling system limits responsiveness and flexibility. As a result, existing solutions fall short of providing an approach to managing individual units within a shared cooling environment.

At least one embodiment discloses a secondary or “mobile” isolation coolant distribution unit (CDU) that can be used to cool a liquid-cooled server during maintenance or testing, or when additional/supplemental cooling is otherwise needed. In at least one embodiment, a valve system can be used that allows for connection of a mobile isolation CDU, otherwise referred to as a secondary CDU, as well as switching of the liquid flow from that of a facility CDU to the mobile CDU, while maintaining constant pressure and flow through the respective cooling loop(s) via one or more pressure balancing systems that may, in example embodiments, increase the pressure going into a server and decrease the pressure coming out of the server, or vice versa. These pressure balancing systems may include, without limitation, pressure sensors, regulators, and other such elements useful for adjusting a pressure of a flow of fluid. In other embodiments, the pressure balancing systems may be attached to a secondary cooling loop, to adjust the pressure of the mobile isolation CDU to match that of the data center CDU, but other such placements or uses are possible as well within the scope of the various embodiments. Quick disconnects can be used to disconnect the hoses to the facility CDU, thus isolating the server from the facility CDU so the facility CDU or server can be serviced, etc. This can be performed without interrupting operation of the server. In some embodiments, an isolation CDU may be installed in the rack instead of being mobile and able to be attached to any of a number of different servers. In example embodiments, a quick disconnect may include a coupling mechanism that allows for the rapid connection and disconnection of hoses or pipes. In some example embodiments, this mechanism may consist of two mating halves: one half is attached to the hose or pipe, while the other is integrated into the equipment, such as a server or cooling unit. As a nonlimiting example, in liquid cooling systems, quick disconnects enable technicians to easily detach coolant hoses from servers for maintenance or replacement without disrupting the entire cooling loop.

Conventional methods used for curing thermal interface materials (TIM) in applications have faced several challenges. For example, it may be necessary to hold TIM at specific temperatures for extended periods to achieve optimal thermal characteristics. Some current practices, such as using GPU loads to generate the required heat, are not only dependent on precise tuning but also require consistent manufacturing conditions. This reliance on specific workloads complicates the curing process, especially in environments where manufacturing occurs across multiple sites, leading to variability and inconsistency in TIM performance. Additionally, alternative curing methods, such as baking entire systems in an oven, face several problems. For large rack-mounted servers, this approach can be impractical due to the potential damage that high temperatures may inflict on sensitive components and plastics within the system. These limitations hinder the ability to reliably cure TIM across different manufacturing scenarios and can lead to compromised thermal performance of cooling solutions.

Approaches in accordance with various illustrative embodiments also provide for the cooling of heat-generating electronic components, and in particular to the use of liquid cooling in computer servers. A cooling plate of a cooling system is often attached to heat-generating components using a patch of thermal interface material (TIM), which needs to undergo a curing process where the TIM patch is held at a specific temperature (or variation in temperature) for an extended period of time before the TIM exhibits the appropriate thermal characteristics. Prior approaches rely on applying a load to a processor, such as a GPU, to generate the heat for an attached TIM, but this requires precise tuning and load control for each specific type of system or component applying the load. In at least one embodiment of the present disclosure, a “cooling” loop from a coolant distribution unit (CDU) can be attached to one or more cold plates in a server (that is unpowered) and can provide a flow of heated fluid that can be used to cure the TIMs attached to the cold plates. A load may be applied to heat the liquid, and a feedback loop can be used to ensure the proper liquid temperature over the curing period in particular if a dynamic temperature cure is desired or necessary. Because such a loop is system-and/or component-agnostic, multiple TIMs can be cured simultaneously using the same flow of heated liquid. Such an approach can also provide improved consistency of curing over prior approaches. After curing, the liquid can be cooled (or different liquid used), and the cooling loop can be used for cooling of the server during operation. In example embodiments, a dynamic temperature cure may refer to a curing process for thermal interface material (TIM) that involves actively adjusting and maintaining the temperature of the curing medium throughout the curing period.

This approach could involve varying the temperature of the heated liquid flow in response to specific parameters, such as the thermal characteristics of the TIM being cured, ambient conditions, or even changes in heat generation during different phases of curing. By dynamically regulating temperature, this method aims to optimize the curing process for each specific TIM patch, ensuring that it reaches its ideal thermal performance characteristics more consistently and efficiently.

Conventional solutions for managing the cooling and power requirements of data center components have faced challenges in dynamic environments where equipment is frequently added or removed. One of these challenges is the need for precise adjustments to coolant distribution units (CDUs) and other cooling mechanisms in response to these changes. In pre-planned data centers, specific calculations are required to account for airflow rates, total cooling capacity, and liquid cooling flow rates. However, as configurations change, maintaining optimal performance may become increasingly complex. Manual tuning in such scenarios can lead to delays and errors that may result in downtime. Each component within a rack—such as compute trays, switches, and fans—has specific thermal management needs that must be monitored and adjusted. Conventional methods may fail to provide real-time data or automated responses necessary for efficient operation, making it challenging to quickly adapt to fluctuations in equipment configuration. This hampers operational efficiency and heightens the risk of overheating or inadequate cooling.

Approaches in accordance with various illustrative embodiments also provide for the cooling of heat-generating electronic components, as may include the use of liquid cooling in computer servers. In a data center, for example, there may be a number of different resources and components that need to be cooled, and individual resources may have different cooling requirements. In at least one embodiment, a tag (or other readable element) can be attached (or otherwise associated) with the individual components. When such a component is installed (such as a server being placed in a rack), a reader can automatically read the requirements associated with that tag and provide the information to a data center operations management system (or other such system/service). This may include, for example, reading information from an RFID tag (or QR code, NFC tag, etc.) that includes information for specific requirements (e.g., expected flow rate, required cooling capacity, expected pressure, minimum and/or maximum temperature, liquid viscosity requirements, cooling loop configuration, maintenance schedule or alerts, cooling efficiency metrics, pressure drops, heat generation profile, emergency shutdown procedures, etc.) or an identifier that can be used to determine these relevant requirements. The operations management system can aggregate this information for all the respective components to determine whether an appropriate action is to be taken. This may include, for example, adjusting a target flow rate for a coolant distribution unit (CDU), adjusting an expected liquid temperature, or throwing a warning that a requirement has been exceeded or is not being met, etc. In addition to automating cooling system management, such an approach provides additional safety measures by allowing the data center to automatically flag potential cooling system problems.

Variations of this and other such functionality can be used as well within the scope of the various embodiments as would be apparent to one of ordinary skill in the art in light of the teachings and suggestions contained herein.

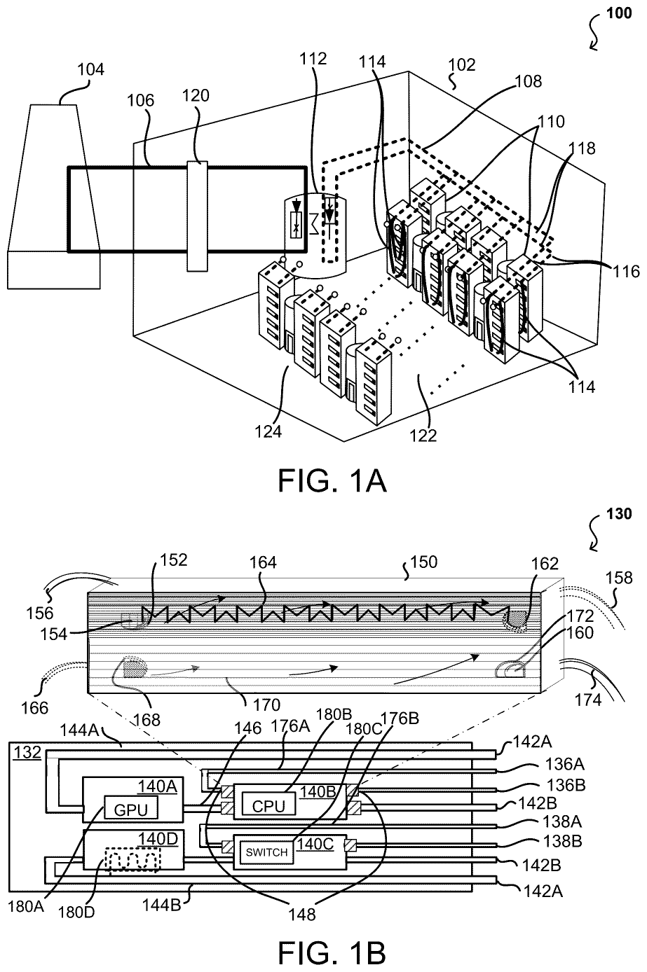

In at least one embodiment, various heat-generating components may operate in a computing environment such as a data center 100, as illustrated in FIG. 1A, which has operational systems, such as cooling, temperature regulation, and power systems, subject to improvements described herein. In at least one embodiment, numerous specific details are set forth to provide a thorough understanding, but concepts herein may be practiced without one or more of these specific details. In at least one embodiment, data center cooling systems can respond to sudden high heat requirements caused by changing computing-loads in present day computing components. In at least one embodiment, as these requirements are subject to change or tend to range from a minimum to a maximum of different cooling requirements, these requirements must be met in an economical manner, using an appropriate cooling system. In at least one embodiment, for moderate to high cooling requirements, liquid cooling system may be used. In at least one embodiment, high cooling requirements are economically satisfied by localized immersion cooling. In at least one embodiment, these different cooling requirements also reflect different heat features of a data center. In at least one embodiment, heat generated from these components, servers, and racks are cumulatively referred to as a heat feature or a cooling requirement, as a cooling requirement must address a heat feature entirely.

In at least one embodiment, a data center liquid cooling system is disclosed. In at least one embodiment, this data center cooling system addresses heat features in associated computing or data center devices, such as in graphics processing units (GPUs), a Data Processing Unit (DPU), switches, dual inline memory module (DIMMs), or central processing units (CPUs); data processing units (DPUs), quantum processing units (QPUs), a plurality of parallel processing units (PPUs), and application-specific integrated circuits (ASICs) memory module, or power supply. In at least one embodiment, these components may be referred to herein as high heat density computing components. Furthermore, in at least one embodiment, an associated computing or data center device may be a processing card having one or more GPUs, switches, or CPUs thereon. In at least one embodiment, each of GPUs, switches, and CPUs may be a heat-generating feature of a computing device. In at least one embodiment, a GPU, a CPU, or a switch may have one or more cores, and each core may be a heat-generating feature. In some embodiments, the local qubits of each QPU may be configured to perform the one or more operations associated with the quantum algorithm on the QPU that the local qubits are associated with.

In at least one embodiment, an exemplary data center 100 can be utilized as illustrated in FIG. 1A, which has a cooling system subject to improvements described herein. In at least one embodiment, a data center 100 may be one or more rooms 102 having racks 110 and auxiliary equipment to house one or more servers on one or more server trays. In at least one embodiment, a data center 100 is supported by a cooling tower 104 located external to a data center 100. In at least one embodiment, a cooling tower 104 dissipates heat from within a data center 100 by acting on a primary cooling loop 106. In at least one embodiment, a cooling distribution unit (CDU) 112 is used between a primary cooling loop 106 and a second or secondary cooling loop 108 to enable extraction of heat from a second or secondary cooling loop 108 to a primary cooling loop 106. In at least one embodiment, a secondary cooling loop 108 can access various plumbing into a server tray as required, in an aspect. In at least one embodiment, cooling loops 106, 108 are illustrated as line drawings, but a person of ordinary skill would recognize that one or more plumbing features may be used. In at least one embodiment, flexible polyvinyl chloride (PVC) pipes may be used along with associated plumbing to move fluid along in each provided cooling loop 106, 108. In at least one embodiment, one or more coolant pumps may be used to maintain pressure differences within cooling loops 106, 108 to enable movement of coolant according to temperature sensors in various locations, including in a room, in one or more racks 110, and/or in server boxes or server trays within one or more racks 110.

In at least one embodiment, coolant in a primary cooling loop 106 and in a secondary cooling loop 108 may be at least water and an additive. In at least one embodiment, an additive may be glycol or propylene glycol. In operation, in at least one embodiment, each of a primary and a secondary cooling loops may have their own coolant. In at least one embodiment, coolant in secondary cooling loops may be proprietary to requirements of components in a server tray or in associated racks 110. In at least one embodiment, a CDU 112 is capable of sophisticated control of coolants, independently or concurrently, within provided cooling loops 106, 108. In at least one embodiment, a CDU may be adapted to control flow rate of coolant so that coolant is appropriately distributed to extract heat generated within associated racks 110. In at least one embodiment, more flexible tubing of rack manifold 114 is provided from a secondary cooling loop 108 to enter each server tray to provide coolant to electrical and/or computing components therein. In at least one embodiment, blind-mate fluid connectors may be used to at least partially remove a need for flex tubing. Further, the server trays herein can use flex tubing, hard piping, or a combination of the two.

In at least one embodiment, tubing 118 that forms part of a secondary cooling loop 108 may be referred to as room manifolds. Separately, in at least one embodiment, further tubing 116 may extend from row manifolds and may also be part of a secondary cooling loop 108 but may be referred to as row manifolds. In at least one embodiment, coolant tubing 114 enters racks as part of a secondary cooling loop 108 but may be referred to as rack cooling manifold within one or more racks. In at least one embodiment, row manifolds 116 extend to all racks along a row in a data center 100. In at least one embodiment, a chiller 120 may be provided in a primary cooling loop within data center 100 to support cooling before a cooling tower. In at least one embodiment, additional cooling loops that may exist in a primary control loop and that provide cooling external to a rack and external to a secondary cooling loop, may be taken together with a primary cooling loop and is distinct from a secondary cooling loop, for this disclosure.

In at least one embodiment, in operation, heat generated within server trays of provided racks 110 may be transferred to a coolant exiting one or more racks 110 via flexible tubing of a row manifold 116 of a second cooling loop 108. In at least one embodiment, second coolant (in a secondary cooling loop 108) from a CDU 112, for cooling provided racks 110, moves towards one or more racks 110 via provided tubing. In at least one embodiment, second coolant from a CDU 112 passes from one side of a room manifold 118 having tubing, to one side of a rack 110 via a row manifold 116, and through one side of a server tray via different tubing 114. In at least one embodiment, spent or returned second coolant (or exiting second coolant carrying heat from computing components) exits out of another side of a server tray (such as enter left side of a rack and exits right side of a rack for a server tray after looping through a server tray or through components on a server tray). In at least one embodiment, spent second coolant that exits a server tray or a rack 110 comes out of different side (such as exiting side) of tubing 114 and moves to a parallel, but also exiting side of a row manifold 116. In at least one embodiment, from a row manifold 116, spent second coolant moves in a parallel portion of a room manifold 118 and is going in an opposite direction than incoming second coolant (which may also be renewed second coolant), and towards a CDU 112.

In at least one embodiment, spent second coolant exchanges its heat with a primary coolant in a primary cooling loop 106 via a CDU 112. In at least one embodiment, spent second coolant may be renewed (such as relatively cooled when compared to a temperature at a spent second coolant stage) and ready to be cycled back through a second cooling loop 108 to one or more computing components. In at least one embodiment, various flow and temperature control features in a CDU 112 enable control of heat exchanged from spent second coolant or flow of second coolant in and out of a CDU 112. In at least one embodiment, a CDU 112 may be also able to control a flow of primary coolant in primary cooling loop 106.

In at least one embodiment, exemplary server-level features 130 can be utilized as illustrated in FIG. 1B, which is associated with a cooling system subject to improvements described herein. In at least one embodiment, server-level features 130 as illustrated in FIG. 1B can be associated with cold plates as liquid manifolds. In at least one embodiment, server-level features 130 include a server tray or box 132. In at least one embodiment, a server tray or box 132 includes a server manifold to be intermediately coupled between provided cold plates 140A-140D of a server tray or box 132 and rack manifolds of a rack hosting a server tray or box 132. In at least one embodiment, a server tray or box 132 includes one or more cold plates 140A-140C associated with one or more computing or data center components or devices 180A-180C. In at least one embodiment, the one or more cold plates 140A-140C may be intermediately coupled between an external coolant source, such as the rack manifolds of a rack hosting a server tray or box 132, and provided components of the server tray or box 132 or the rack. In at least one embodiment, one or more cold plates 140A-140C may be dual-cooling-enabled cold plates having a first distinct path 164 capable of cooling using a first coolant and second a second distinct path 170 capable of cooling using a second coolant concurrently with a first coolant or at separate times. In at least one embodiment, such first distinct path 164 and second distinct path 170 are fins or tubes.

In at least one embodiment, at least one heat sink 140D includes fins and is exposed to an environment of a server tray or box 132 so that cold air from a cold aisle 122 can be used as cooling media through such fins to cool a heat sink 140D before such cold air exits to a hot aisle 124. In at least one embodiment, an associated computing device 180A benefits from cooling provided by such heat sink 140A (that need not have a cold plate or coolant for cooling). In at least one embodiment, therefore, cooling media may be air or single-phase fluid. In at least one embodiment, at least one TTV 180D is illustrated to indicate that testing of a data center cooling system may be performed using cold plates as liquid manifolds for data center cooling systems.

In at least one embodiment, one or more server-level cooling loops 144A, 144B may be provided between one or more cold plates 140A-140C and an external source, such as rack manifolds, for single or dual-cooling-enabled cold plates. In at least one embodiment, each server-level cooling loop 144A, 144B includes an inlet line 142A and an outlet line 142B. In at least one embodiment, when there are series configured cold plates 140A, 140B, an intermediate line 146 may be provided. In at least one embodiment, however, for cold plates as liquid manifolds, distinct fluid paths, via provided lines 176A, may be established to pass a first coolant through first provided lines 136A, 136B and a second coolant through second provided lines 138A, 136B. In at least one embodiment, there may be separate server rack cooling manifolds for each type of coolant used.

In at least one embodiment, one or more cold plates 140A-140C may be only single-coolant-enabled cold plates or only dual-coolant-enabled cold plates. In at least one embodiment, one or more cold plates 140A-140C, when adapted for dual purpose, may support distinct ports and channels for a first secondary coolant of a secondary cooling loop and for a second secondary coolant (or local coolant) circulated from a local coolant source. In at least one embodiment, a first secondary coolant for cooling may be provided to one or more cold plates 140A-140C via provided inlet and outlets 136A, 136B. In at least one embodiment, a second secondary coolant may be provided to one or more cold plates 140A-140C via provided inlet and outlets 138A, 138B. In at least one embodiment, all such one or more cold plates, lines, or loops may be terminated using flow controllers having mechanical coupling and electrical coupling features. In at least one embodiment, electrical coupling features enable at least one processor to control aspects of a flow controller for cold plates as liquid manifolds.

In at least one embodiment, a server tray 132 is an immersive-cooled server tray that may be flooded by fluid. In at least one embodiment, a fluid for an immersive-cooled server tray may be a dielectric engineered fluid capable of being used in an immersive-cooled server. In at least one embodiment, a secondary coolant or local coolant may be used to cool engineered fluid. In at least one embodiment, a local coolant may be used to cool engineered fluid when a primary cooling loop associated with a secondary cooling loop circulating a secondary coolant has failed or is failing. In at least one embodiment, at least one cold plate, therefore, has ports for a secondary cooling loop and for a local coolant cooling loop from a local coolant source that is part of a system adapted for cold plates as liquid manifolds. In at least one embodiment, such a cold plate can support a local coolant that may be activated in an event of a failure in a primary cooling loop.

In at least one embodiment, at least one dual-cooling cold plate 140B, 150 may be configured to work alongside regular cold plates 140A, 140C. In at least one embodiment, a three-dimensional (3D) blow-up illustration (cold plate 150) provides internal detail of at least some features that may be included in a dual-cooling cold plate or a regular cold plate. In at least one embodiment, a tear-through of a cold plate 150 illustrates microchannels 170 and a distinct section for tubes 164 functioning as heat dissipation features, as illustrated in FIGS. 1A, 1B. In at least one embodiment, a distinct second section may be provided side-by-side and have heat dissipation features in at least a part of such a cold plate. In at least one embodiment, a local coolant-enabled cold plate may have only tubes 164 and no microchannels 170 therein.

In at least one embodiment, a dual-cooling cold plate 150 has distinct paths 164, 170 for secondary coolant of a secondary cooling loop, for local coolant of a local cooling loop, and for local coolant from a local coolant source. In at least one embodiment, in a use case of an immersive-cooled server, fluid that may be a dielectric engineered fluid may be adapted for both, a cold plate application and an immersive-cooled server tray application. In at least one embodiment, some microchannels 170 are paths provided by fins or other such aspects that raise internally and perpendicularly to a base of a cold plate section, and that have gaps therebetween for coolant or fluid flow. In at least one embodiment, some microchannels 170 are fluid pathways in a different cold plate section of a cold plate 150.

In at least one embodiment, reference to a cold plate, along with its dual-cooling features, may imply a reference to a cold plate that can support at least two types of cooling loops, unless otherwise stated. In at least one embodiment, both types of cold plates receive at least local coolant for cooling, but one type can support both, a secondary cooling loop or a local cooling loop and local coolant from a local coolant source. In at least one embodiment, a standard coolant, such as facility water, may be used in a secondary cooling loop.

In at least one embodiment, a fluid or local coolant may only support cold plate usage and may not be available for immersive cooling. In at least one embodiment, each type of cold plate receives local coolant that may be associated with different secondary or local coolant from respective local cooling loops or other cooling loops interfacing with a primary cooling loop. In at least one embodiment, in situations where different fluids (such as secondary coolants and local coolants) are used in a data center cooling system, then a secondary or local cooling loop may be suited for a dual-cooling cold plate, along with local coolant. In at least one embodiment, secondary or local coolant may be supported by cold plates as liquid manifolds, so that different channels may be used for each of a local coolant and for different secondary coolants.

In at least one embodiment, provided valve covers 154 are mechanical features of associated flow controllers that also have corresponding electronic features (such as at least one processor to execute instructions stored in associated memory and to control mechanical features for associated flow controllers). In at least one embodiment, sensors can be used to provide feedback to adjust inlet local coolant through a cold plate.

In at least one embodiment, each valve may be actuated by an electronic feature of an associated flow controller. In at least one embodiment, electronic and mechanical features of provided flow controllers are integrated. In at least one embodiment, electronic and mechanical features of provided flow controllers are physically distinct. In at least one embodiment, reference to flow controllers may be to one or more of provided electronic and mechanical features or to their union but is at least in reference to features enabling control of flow of coolant or fluid through each cold plate or an immersion-cooled server tray or box.

In at least one embodiment, electronic features of provided flow controllers receive control signals and assert control over mechanical features. In at least one embodiment, electronic features of provided flow controllers may be actuators or other electronic parts of other similar electromechanical features. In at least one embodiment, flow pumps may be used as flow controllers. In at least one embodiment, impellers, pistons, or bellows may be mechanical features, and an electronic motor and circuitry form electronic features of provided flow controllers. In at least one embodiment, circuitry of provided flow controllers may include processors, memories, switches, sensors, and other components, altogether forming electronic features of provided flow controllers.

In at least one embodiment, provided ports 152, 162, 168, 172 of provided flow controllers are adapted to either allow entry or to allow egress of an immersive fluid. In at least one embodiment, flow controllers 148 may be associated with fluid lines 176A, 176B (also 156, 158) that enable entry and egress of a local coolant to a cold plate 140A-140C. In at least one embodiment, other flow controllers may be similarly associated with coolant lines 142A, 146, 142B (also 166, 174) to enable entry and egress of a secondary coolant to a cold plate 140B, 140D.

In at least one embodiment, a local coolant enters provided fluid lines 176A, 176B via dedicated inlet and outlet lines 138A, 138B. In at least one embodiment, a cold plate 140A-140D as a server manifold is adapted with channels therein to support distinct paths to distinct fluid lines 176A, 176B (also 156, 158) and to any remaining loops 144A, 144B that are associated with secondary coolant inlet and outlet lines 136A, 136B. In at least one embodiment, there may be multiple cold plates 140A-140D as a server manifold to support local coolant and a distinct secondary coolant. In at least one embodiment, there may be multiple cold plates 140A-140D as a server manifold to support entry and egress, distinctly, for each of a local coolant and of a secondary coolant. In at least one embodiment, a local coolant is singularly used without a secondary cooling loop.

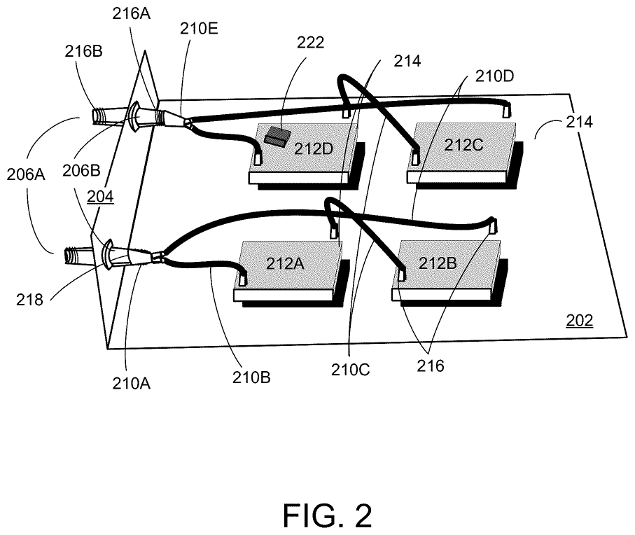

FIG. 2 illustrates server-level features 200 associated with cold plates as liquid manifolds in computer hardware for data center cooling systems. In at least one embodiment, a data center cooling system, therefore, includes a server tray or box 202 having a surface 204 with one or more external flow controllers 206A and one or more internal flow controller 206B mounted removably thereon. In at least one embodiment, multiple flow controllers 206A, 206B may be provided so that entry of coolant occurs through one of such flow controllers and egress of coolant occurs through a different one of such flow controllers.

In at least one embodiment, each flow controller 206A, 206B includes an associated coupling 216A, 216B. In at least one embodiment, a sensor 222 can monitor a secondary coolant through a cold plate 212A, 212B, 212C, 212D. In at least one embodiment, such monitoring may be to a return temperature of a secondary coolant from one or more cold plates 212A, 212B, 212C, 212D. In at least one embodiment, such a sensor may be mounted on a rack manifold or a row manifold to sense a cumulative temperature of returned secondary coolant. In at least one embodiment, such a sensor may be able to determine pressure or flow rate of a return secondary coolant. In at least one embodiment, a sensor 222 may be also associated with a supply secondary coolant to provide reference or difference in temperature, pressure, or flow rate of a secondary coolant.

In at least one embodiment, one or more of a first flow controller 206A or a second flow controller 206B can change a flow of a secondary coolant through a flow controller 206A, 206B. In at least one embodiment, an associated coupling 216A, 216B includes push-coupling or threaded-coupling features to enable an external flow controller 218 to fluidly communicate with one or more of a first flow controller or a second flow controller. In at least one embodiment a sensor 222 may be adapted to monitor a flow volume of a secondary coolant that is to pass through a flow controller 206A, 206B.

In at least one embodiment, two flow controllers 206A, 206B may be adapted to close concurrently when a server tray or box 202 is to be disconnected from a rack. In at least one embodiment, two flow controllers 206A, 206B may be adapted to close separately depending on a local or a secondary coolant used, which allows for maintenance of a secondary cooling loop while a local cooling loop is operational to provide redundancy in operations. In at least one embodiment, this prevents leaks when removing a server tray or box from an external coupling, or prevents leaks when removing the cold plate 212A, 212B, 212C, 212D from the server tray or box 202. One or more leakage sensors may also be included, and may be associated with at least one of the server tray or box 202, the cold plates 212A, 212B, 212C, 212D, or other components.

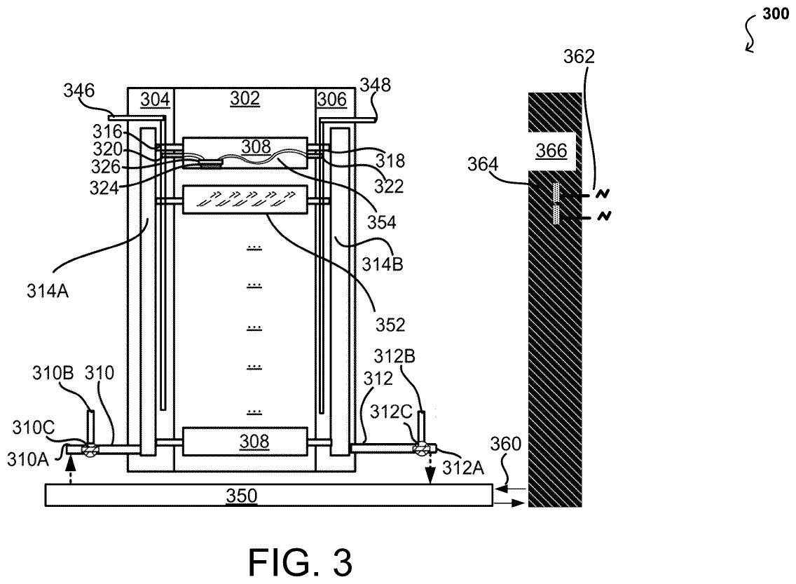

In at least one embodiment, secondary coolant enters a server tray or box 202 via a first flow controller 206A that may be coupled, at its associated coupling 216B, to a rack-side flow controller of a rack cooling manifold, and then to the one or more cold plates 212A, 212B, 212C, 212D via a coolant inlet 210E, as illustrated in FIG. 3. In at least one embodiment, secondary coolant flows through one or more flow controllers 206A, 206B. In at least one embodiment, FIG. 2 also illustrates an associated coupling 216A with a second flow controller 206B for coupling with a server-side flow controller. In at least one embodiment, one flow controller may be used for controlling a change in a flow or a pressure for a secondary coolant.

In at least one embodiment, as illustrated, valve covers that are actuated to different openness or closeness within a flow controller 206A, 206B enable a change in a flow rate or a flow volume of a secondary coolant therethrough. In at least one embodiment, impeller pumps that are controlled at different revolutions per minute (rpm) may be used to change this for a secondary coolant therethrough. In at least one embodiment, an impeller pump may be enabled to do this, but may require an associated valve cover in addition to an impeller. In at least one embodiment, a flow controller 206A, 206B may have a combination of a valve cover and an impeller flow controller representing two different flow controllers or a single flow controller depending on a configuration to perform different actions, including to stop or change a flow of a secondary coolant.

In at least one embodiment, secondary coolant flows through one or more flow controllers 206A, 206B, a coolant inlet 210A, and a cold plate 212A, 212B, 212C, 212D that may be an inlet server cooling manifold. In at least one embodiment, such a server cooling cold plate 212A, 212B, 212C, 212D as a manifold may be used so that multiple server-level cooling loops may be established without further flow controllers for each server-level cooling loop. In at least one embodiment, at least two distinct server-level cooling loops are illustrated in FIG. 2. In at least one embodiment, secondary coolant enters a first cold plate 212A, from an external source via a coolant inlet 210B, to cool an associated computing device 214. In at least one embodiment, heat is removed from a such an associated computing device 214 by transfer to a secondary coolant.

In at least one embodiment, if serial cold plates are used in a server-level cooling loop, then an intermediate coolant inlet 210C enables flow of secondary coolant from a first cold plate 212A to a second cold plate 212B that is associated with a different computing device 214. In at least one embodiment, a coolant outlet 210D enables coolant to be passed back to cold plates 212A, 212B, 212C, 212D as a manifold that may act as an outlet server cooling manifold. In at least one embodiment, however, a single cooling cold plate 212A, 212B, 212C, 212D as a manifold having channels for inlet and for outlet may be used with one or more flow controllers 206A, 206B. In at least one embodiment, each such coolant tube or line may be associated with a flow controller and/or a leak sensor so that leaks are prevented upon disconnection of any such coolant tube or line.

In at least one embodiment, secondary coolant then flows out from a server cooling cold plate 212A, 212B, 212C, 212D as a manifold through another flow controller 206 and to a rack outlet cooling manifold that is associated with a flow controller 206A, 206B at an outlet side via its own flow controllers. In at least one embodiment, one or more sensors 222 may be coupled to a processor that is external to such a flow controller 206A, 206B. In at least one embodiment, multiple sensors 222 communicate to an external processor that may be a part of a BMS or a building management system. In at least one embodiment, a control unit (such as a last server tray or box 308 of a rack 302 in FIG. 3) may be provided as a server tray or box form-factor within a rack to control all flow controllers within a rack.

In at least one embodiment, therefore, a processor may be adapted to receive input from a state sensor 222. In at least one embodiment, such input or sensor input may be about a flow controller 206A, 206B. In at least one embodiment, sensor input is as to temperature, flow rate, flow volume, or pressure associated with secondary coolant through one or more flow controllers 206A, 206B. In at least one embodiment, an action of a processor may be triggered based in part on such input from a sensor. In at least one embodiment, such an action may be an output from a processor to a primary flow controller, such as reference numeral 364 in FIG. 3. In at least one embodiment, a secondary coolant may be PG-25®, deionized water, and HC-30®.

FIG. 3 illustrates rack-level features 300 associated with using cold plates as liquid manifolds in computer hardware for data center cooling systems. In at least one embodiment, such rack-level features 300 include one or more racks 302 in one or more rows. In at least one embodiment, each row may be associated with its own cooling manifold 350 that is associated with a secondary coolant for dual purpose cold plates, although only a secondary coolant-based cooling or only a local coolant-based cooling may be enabled for one or all of such racks 302 in FIG. 3 using dedicated cooling manifolds 346, 348.

In at least one embodiment, secondary or local coolant flows through a further inlet 316 of a server tray or box 308, to a cold plate 326 of an associated computing device 324, out of an outlet 318 of a server tray or box 308, through a rack cooling manifold 314B, into a further outlet 312B, through another flow controller 312C, and out of an outlet line 312A to a row cooling manifold 350 that may be a same or a different row cooling manifold than an inlet side row cooling manifold. Further, a row cooling manifold 350 or a rack cooling manifold 314A, 314B may have different channels therein to support inlet and outlet flows.

Text test In at least one embodiment, some server trays or boxes 308 may be associated with secondary coolant-based cooling, while other server trays or boxes may be associated with a local coolant-based cooling, and some others may be associated with two-phase cooling. In at least one embodiment, in each such case, server trays or boxes 308 are associated with a CDU 366 via lines 362, where such a CDU 366 supports using cold plates as liquid manifolds in computer hardware. In an embodiment, coolant may flow 360 between the CDU 366 and a coolant source via lines 362 using primary flow controllers 364.

In at least one embodiment, flow paths may be enabled to a dual-purpose cold plate 326, through one or more rack cooling manifolds 314A, 314B that is within a rack 302. In at least one embodiment, a singular rack cooling manifold may support entry and egress of a secondary coolant and a separate rack cooling manifold may support entry and egress of a local coolant. In at least one embodiment, however, separate rack cooling manifolds 314A, 314B may be used for each of entry and of exit of each of such secondary coolant and local coolant depending on if both are used or if each is used independently.

In at least one embodiment, such a dual-purpose cold plate 326, which may act as a manifold, is associated with a computing device 324 that may have a cooling requirement that may be addressed by a secondary coolant, a local coolant, or a combination of coolants. In at least one embodiment, such a flow path allows secondary or local coolant from a row cooling manifold 350 to enter into and exit from one or more rack cooling manifolds 314A, 314B. In at least one embodiment, secondary or local coolant may flow 360 between a row cooling manifold 350 and the CDU 366. In at least one embodiment, such secondary coolant flows through a row cooling manifold 350, through an inlet 310A of a rack 302, through a flow controller 310C adapted to switch between at least two coolant paths (or a coolant path and a local coolant path), through an inlet 310, and into a rack cooling manifold 314A. In at least one embodiment, such secondary or local coolant enters a cold plate 326 and addresses one cooling requirement associated with a cold plate 326 and/or its associated computing device 324. In at least one embodiment, a separate flow controller than an illustrated flow controller 310C may be used for local coolant.

In at least one embodiment, a local coolant may be caused to occur via different flow paths, such as an inlet or inlet lines from a distinct inlet manifold 346 provided at a top of a rack 302, through a channel of a rack cooling manifold 314A or a dedicated local coolant manifold 346, through direct lines 320, 354, 322 to a cold plate 326, and out of outlet lines of a further distinct manifold 348 at a top of a rack 302. In at least one embodiment, secondary or local coolant flows through a further inlet 316 of a server tray or box 308, to a cold plate 326 of an associated computing device 324, out of an outlet 318 of a server tray or box 308, through a rack cooling manifold 314B, into a further outlet 312, through another flow controller 312C, and out of an outlet line 312A to a row cooling manifold 350 that may be a same or a different row cooling manifold than an inlet side row cooling manifold. Further, a row cooling manifold 350 or a rack cooling manifold 314A, 314B may have different channels therein to support inlet and outlet flows.

In at least one embodiment, a rack 302 can, therefore, include distinct local coolant flow paths rather than secondary coolant flow paths. In at least one embodiment, such direct lines may be available within each of a server trays or boxes 308 of a rack 302 and may also be available within an immersive server 352 of a rack 302. In at least one embodiment, such local coolant enters a cold plate 326 and addresses a second cooling requirement that may be associated with a cold plate 326 and/or its associated computing device 324. In at least one embodiment, a cold plate 326 is either a coolant cold plate, a local coolant cold plate, or a dual cooling cold plate supporting secondary coolant and local coolant, with a cold plate as a manifold.

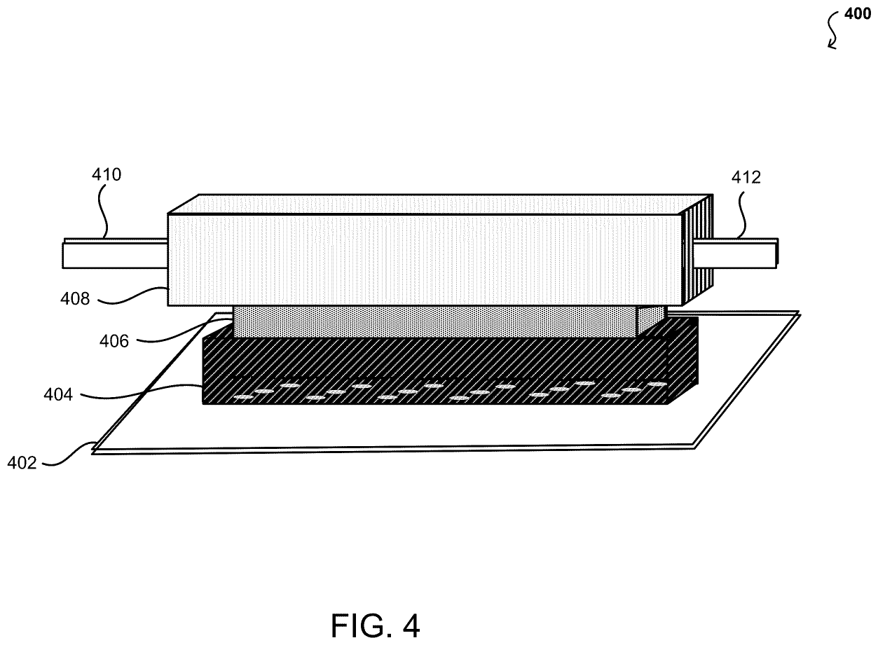

FIG. 4 illustrates component-level features 400 associated with cold plates as liquid manifolds in computer hardware for a data center liquid cooling system, according to at least one embodiment. The component-level features include a computing or data center device formed of one or more of components 402, 404. In at least one embodiment, component 402 is a board or card, such as a printed circuit board (PCB) or printed circuit card that is enveloped and shielded to protect components therein. In at least one embodiment, component 404 is a chip or semiconductor device, such as a CPU, a GPU, or a switch. In at least one embodiment, even though only one component 404 is illustrated, the PCB 402 may have multiple components mounted thereon. In at least one embodiment, the component 404 may include multiple die (such as a multi-core processor device). In at least one embodiment, the cores may be stacked or distributed. In at least one embodiment, the components 402, 404 may have different heat-generating features represented by at least locations of the die therein. In the case of the PCB 402, when there are multiple components 404 thereon, each component may be a heat-generating feature.

In at least one embodiment, a cold plate 408 as a manifold is associated with the computer device. In the illustration of FIG. 4, the cold plate 408 is associated with the computing device 404. In at least one embodiment, the cold plate 408 may extend throughout the dimensions of the PCB 402 to provide direct or indirect contact cooling to one or more computing components on the PCB 402. In at least one embodiment, when a graphics processing card is the computing device, the cold plate 408 extends over the entire card, but the channels therein may enable concentration of coolant or the flow of coolant over areas of the card having processor or memory-intensive computing devices. The computing device may, therefore, have further computing devices associated therewith.

In at least one embodiment, the cold plate 408 is associated with the computing device 404 via a thermal transfer layer 406. The thermal transfer layer may be a layer having one or more of silicon, a thermal interface material, or air. In at least one embodiment, there may be no thermal transfer layer 406 and the cold plate 408 may be directly associated with the computing device 404. The cold plate 408 may have at least one inlet for coolant inlet line 410 and at least one outlet for coolant outlet line 412. The at least one inlet line 410 may receive a flow of liquid coolant from a source external to the server. The at least one outlet line 412 may provide the flow of coolant to one or more components of the server. The cold plate 408 may also include at least one additional outlet line to provide the flow of coolant to external source and may include at least one additional inlet line to receive the flow of coolant from the one or more components of the server.

An example cold plate can distribute liquid coolant in computer hardware, according to at least one embodiment. In at least one embodiment, a cold plate may have source fluid adapters and distribution fluid adapters as inlets and outlets of the cold plate. The source fluid adapters may enable receipt and egress of the liquid coolant between the cold plate and at least an external liquid coolant source or interface, such as the cooling tower or primary cooling loop illustrated in FIG. 1A, or the rack manifold or the CDU illustrated in FIG. 2. The distribution fluid adapters may enable receipt and egress of the liquid coolant between the cold plate and one or more other components, such as a server the cold plate is located in. The server may also include circuit boards, such as printed circuit boards (PCB), which are provided cooling from the cold plate or include components which are provided cooling from the cold plate. In at least one embodiment, coolant or other fluid flows, as indicated by the arrows, into source inlet fluid adapter, through the cold plate, and out of the source outlet fluid adapter, transferring fluid with the fluid source. The coolant or other fluid may also flow out of the distribution outlet fluid adapter and into the distribution source inlet fluid adapter, transferring fluid with the other components. The cold plate may use distribution fluid adapters to also serve as a manifold and distribute the flow of cooling fluid to other hardware components associated with the cold plate of a system associated with the cold plate, such as a server tray or box, which may be removable from a server rack. In an embodiment, the server tray or box may include more than one cold plate to serve as manifolds. The cold plate may include any number of fluid adapters in various combinations to transfer cooling fluid. The cold plate may also include one or more channels connected to the fluid adapters. In at least one embodiment, the flow of the coolant refers to flow rate or flow volume of the coolant in cold plate or into or out of the cold plate. In at least one embodiment, the coolant is in a dynamic state and is continuously moving through the cold plate.

When using liquid cooling or liquid coolant with a server or other such electronic device, it may be necessary to perform an action such as to isolate a server from a cooling system in order to perform maintenance or other such tasks with respect to the server. Such isolation or “quarantine” may be less straightforward for liquid-cooled systems than would normally be experienced for air cooled servers or devices. For example, each of a number of large coolant distribution units (CDU) may be used to cool (or remove heat from) many different units such as servers, and the plumbing involved can make moving or disconnecting a server or other such component challenging. Further, many approaches require powering down the server, which impacts availability and increases overall system cost due to the need to have excess resource capacity available if one or more servers need to be taken offline.

Approaches in accordance with at least one embodiment can allow for use of a secondary cooling loop in such a cooling or heat removal system. A flow of cooling liquid can then be switched over between cooling loops as needed. In one example implementation, a server in a rack on casters may be connected to a large CDU or facility water in a primary flow of cooling liquid. A mobile CDU, mobile isolation CDU, or other secondary CDU may be moved into position near the rack, for example, or a secondary CDU may be installed in the rack itself, among other such options. This mobile isolation CDU or secondary CDU may include a unit housing which houses one or more elements or components described herein, including without limitation one or more transport mechanisms which allow the mobile isolation CDU or secondary CDU to be positioned with respect to and connected to the valve system or cooling system of any instance of a computer hardware such as, without limitation, servers, network switches, storage arrays, or any suitable computer hardware. In example embodiments, the unit housing may also include a source of liquid coolant. A valve (or other such mechanism) can be used to manually, or automatically, switch the flow of liquid coolant for the server and/or rack from the primary cooling loop from the large CDU to the secondary loop for the mobile or local CDU. Such a switch may be performed “live,” or without powering down the servers and/or other components in (or otherwise associated with) the rack. The rack may then be at least partially decoupled from the rest of the data center infrastructure, for example, which can be beneficial for tasks such as servicing, testing, or containment, among other such options.

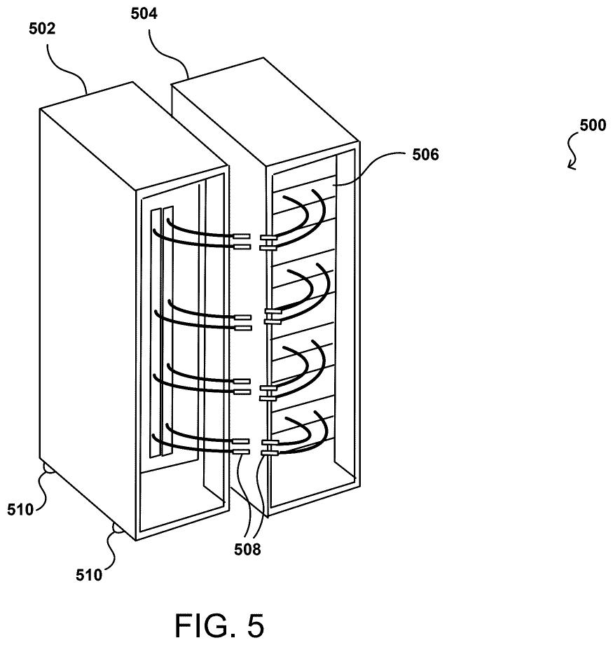

FIG. 5 illustrates a configuration 500 including a mobile or secondary coolant distribution unit (CDU) 502, or heat exchanger, next to a server rack 504 that can include up to a maximum number of servers 506. A cooling loop(s) from the mobile CDU 502 can be connected to the cooling loop(s) of the individual servers 506 in the rack 504. There may be an inlet and an outlet for each server 506, which can be connected to the heat exchanger or mobile CDU 502 using appropriate connectors 508. In at least one embodiment, it can be desirable to use such a heat exchanger or mobile CDU 502 as a type of isolation CDU or a secondary CDU. For example, the mobile CDU 502 can include one or more transport mechanisms integrated into the housing of the CDU 502, such as wheels 510, and can be moved proximate to a server rack 504 wherein there are one or more servers 506 that require liquid cooling. The mobile CDU 502 may include any number of wheels or other transport mechanisms. In other example, embodiments, the transport mechanisms can include one or more sled bases for sliding the CDU 502 into position. A set of quick connectors 508 can be used to connect the mobile CDU to the appropriate servers 506 or server racks 504, in order to isolate those servers from a primary cooling loop, as may be associated with a main or data center CDU. The mobile CDU 502 can include a type of manifold that can be used for liquid cooling as discussed in more detail elsewhere herein. Once connected, the flow of cooling liquid can be redirected to a secondary cooling loop through the mobile CDU 502. Such a mobile CDU 502 can be moved together with a rack 504 if needed, such as where the rack 504 is to be moved to a certain location for repair. The mobile CDU 502 can be moved together with the rack 504 since the rack 504 is no longer tied into the facility liquid. Such an approach can allow for zero downtime on servers 506, unless there is an actual problem with a server 506 that requires it to be taken offline. The mobile CDU 502 can provide a sufficient flow rate that can match that of a data center CDU, for example, such as flows around 20 liters per second or up to about 150 liters per second, among other such values or ranges.

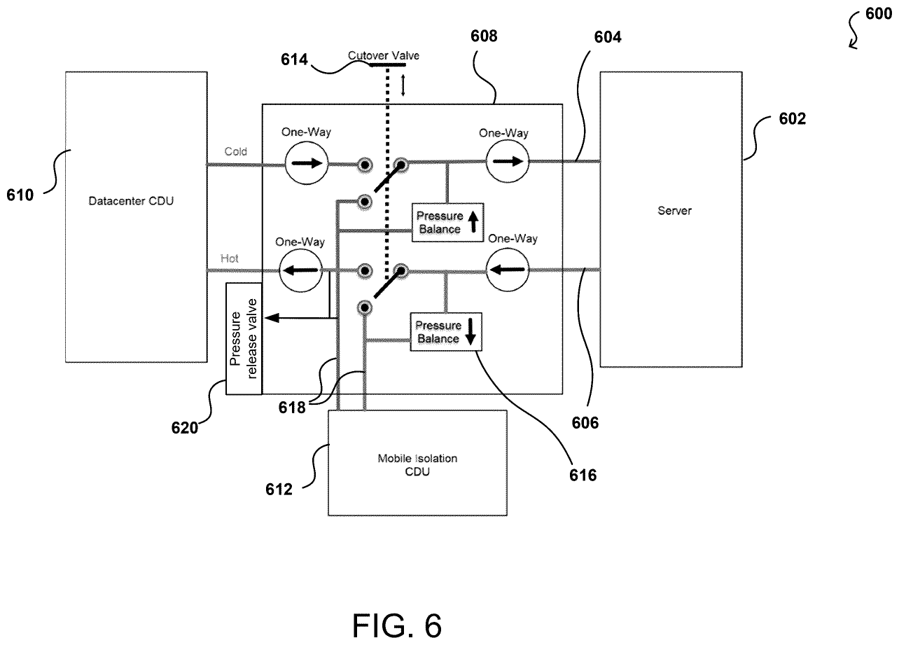

In order to use such an approach, however, a mechanism is needed to allow for sufficiently rapid switchover between a primary cooling loop and a secondary cooling loop. FIG. 6 illustrates a schematic view 600 of a system that allows for switchover between a primary cooling loop and a secondary cooling loop, according to at least one embodiment. In this example, a server 602 can receive a flow of cooling liquid through an inlet 604 pipe or hose from a cutover manifold 608, for example, and the heated liquid will flow out of the server 602 in an outlet 606 pipe or hose, etc. The flow of liquid into, and out of, the server 602 can pass through a cutover valve 614 of the cutover manifold 608. The cutover manifold 608 may have one or more connections to a primary cooling CDU or data center CDU 610, a secondary cooling CDU or mobile isolation CDU 612, and at least one cooling loop associated with a server or other computer hardware. The cutover manifold 608 may allow for the cooling loop to be connected to the primary CDU, such as the data center CDU 610, or the secondary CDU, such as the mobile isolation CDU based in part on a setting of the valve system. Moreover, a cutover valve 614 (or manifold valve, etc.) can allow for switching of the flow of liquid to, and from, a data center CDU 610 for a primary cooling loop, to a flow of liquid go, and from, a mobile isolation CDU 612, or other such secondary CDU, of a secondary cooling loop. Such a cutover valve 614 can allow for switching over of the liquid flow while maintaining constant pressure and/or flow, until the changeover is complete between the mobile isolation CDU 612 or secondary CDU and the data center CDU 610. The cutover valve 614 may also allow the changeover to occur without interrupting operation of the computer hardware. In example embodiments, changeover may refer to process of switching the flow of cooling liquid between the primary cooling loop and the secondary cooling loop. In example embodiments, the flow of liquid coolant is able to be concurrently provided by the primary CDU or data center CDU 610 and the secondary CDU or mobile isolation CDU 612. In example embodiments, the mobile isolation CDU 612 or secondary CDU may include at least two connectors 618 which connect the mobile isolation CDU 612 or secondary CDU to the valve system to direct liquid coolant through at least a secondary cooling loop, though in other embodiments, the coolant may be directed through the primary cooling loop or other cooling loops. In some example embodiments, these connectors 618 may include an inlet and outlet to the valve system, although it is understood that in other embodiments, there may be fewer or a greater number of connections than illustrated in FIG. 6. In at least one embodiment, quick disconnects can be used with the cutover valve 614 that can allow for quick and relatively simple disconnection and/or connection hoses of the hoses (or pipes, etc.) to and/or from the server 602, the data center CDU 610, or the mobile isolation CDU 612. Once isolated, the original data center CDU 610 or server can be serviced or otherwise handled separately from each other. In at least one embodiment, for liquid cooling dialysis, for example, a mobile isolation CDU 612 or secondary CDU can either replace or clean the fluid that is to be provided through the inlet 604 or any cooling loop into the server 602. A similar process can be used to service the data center CDU 610.

As illustrated, the cutover manifold 608 can include one or more pressure balancing systems 616, in addition to a cutover valve 614. There may be one pressure balancing system 616 to increase a pressure going into a server and another to decrease the pressure coming out of a server, or vice versa. Such components can be particularly useful because there may be differences in pressure provided by the data center CDU 610 and the mobile isolation CDU 612, but it can be beneficial for the pressure passing through a server 602 to remain substantially constant during normal operation regardless of the source of coolant flow. In this example, the pressure balancing systems are attached to the secondary cooling loop, to adjust the pressure of the mobile isolation CDU 612 to match that of the data center CDU 610, but other such placements or uses are possible as well within the scope of the various embodiments. Such systems may include pressure sensors, regulators, and other such elements useful for adjusting a pressure of a flow of fluid. The ability to regulate pressure also helps to avoid issues that might otherwise be experienced around cutover, as may relate to hammering or knocking, etc. Such a system may also include at least one relief valve or pressure release valves 620 in a case of excess pressure buildup to allow for removal of excess pressure proximate the valve system. As illustrated, the pressure can be balanced in the direction of the flow and in parallel with the cutover valve 614.

Pressure-balancing valves can also help to equalize the pressure on either side of the valve around a cutover event. For example, there may be a period of time where the cutover valve 614 has been adjusted to cause the secondary flow of cooling fluid from the mobile isolation CDU 612 to flow through the server 602, but a primary flow of cooling fluid from the data center CDU 610 is still active and applying pressure near the cutover valve 614. This can result in an increased pressure imbalance, which could lead to problems if the increased pressure is released into the system during or after a cutover. Pressure balancing can help to avoid such pressure spikes, which could potentially exceed the pressure rating of the components inside the fluid loop, hose couplings, quick disconnects, and the like. In at least one embodiment, pressure balancing system can include a mechanical valve that allows fluid to pass on a pressure differential in a single direction.

As mentioned, such switchover can be performed without interrupting operation of the server in at least some embodiments, providing continuous up-time and saving critical capitalization of investment of the server. Such a mobile isolation CDU 612 or secondary CDU can also be used as a pre-deployment tool, where a CDU can be used that pumps pre-heated liquid through a server that can ‘bake and cure’ thermal interface material (TIM) of the internal ICs to ensure correct thermal operation before deployment into a full data center cluster, as will be discussed in detail elsewhere herein. Such an approach can also allow systems that require full redundancy to now not have to have N+N CDUs per server, but could instead have N+1 CDUs for all systems in the data center, where a mobile isolation CDU or a secondary CDU provides the redundancy and be deployed in-situ. One or more connection mechanisms can also allow such a mobile isolation CDU 612 or secondary CDU to be removed from a server 602 while in operation, and then moved and connected to another server that remains in operation, using a separate cutover valve to which that mobile isolation CDU 612 or secondary CDU can be connected.

In various situations, it may be beneficial (if not necessary) to clean or replace cooling fluid when the liquid loop becomes unhealthy. An unhealthy state can occur due to, for example, contamination, leaks, bio-growth, or other such causes. As mentioned, prior approaches typically involved taking at least a portion of the infrastructure offline by, for example, powering down and removing an entire rack from the cooling system. An approach such as that described with respect to FIG. 6 allows for switchover to a secondary or external cooling loop without a need to take a server 602 (or other relevant portion of the infrastructure) offline.

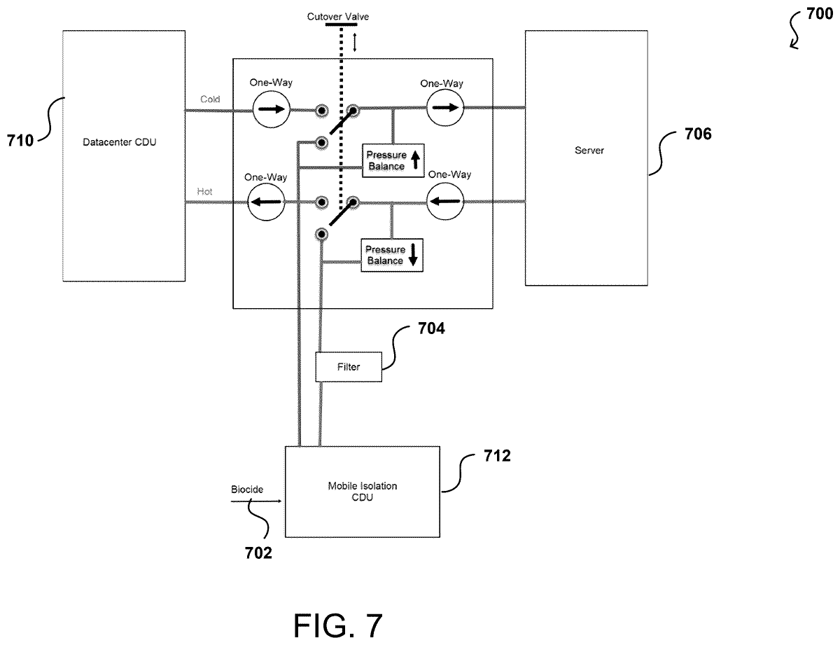

FIG. 7 illustrates an example configuration 700 where cleaning of a cooling fluid can be performed using a secondary cooling loop. In this example, a flow of a biocide 702 (or other chemical, mixture, or microorganism usable to control harmful organisms) can be injected into a mobile isolation CDU 712 or other secondary CDU. The biocide 702 can be directed through the secondary cooling loop and into the cooling loop through the server 706. The flow from the server 706 can pass through at least one filter 704 that can attempt to remove any particulates or impurities from the flow of coolant, such as may correspond to biological material that is removed (or otherwise modified or impacted) by the biocide 702. A mobile isolation CDU 712 or secondary CDU can include one or more sensors for detecting and maintaining the density of additives, such as a biocide 702 or other bio-growth inhibitor. A sensor can detect that the amount of biological growth has exceeded an allowable amount, for example, and this can trigger the system to perform a cleaning or replacement action, as may depend in part upon the type or extent of the biological contamination. In at least one embodiment, separate cleaning processes can be used for the server 706, the cooling loop, the data center CDU 710, or other such components of the cooling system.

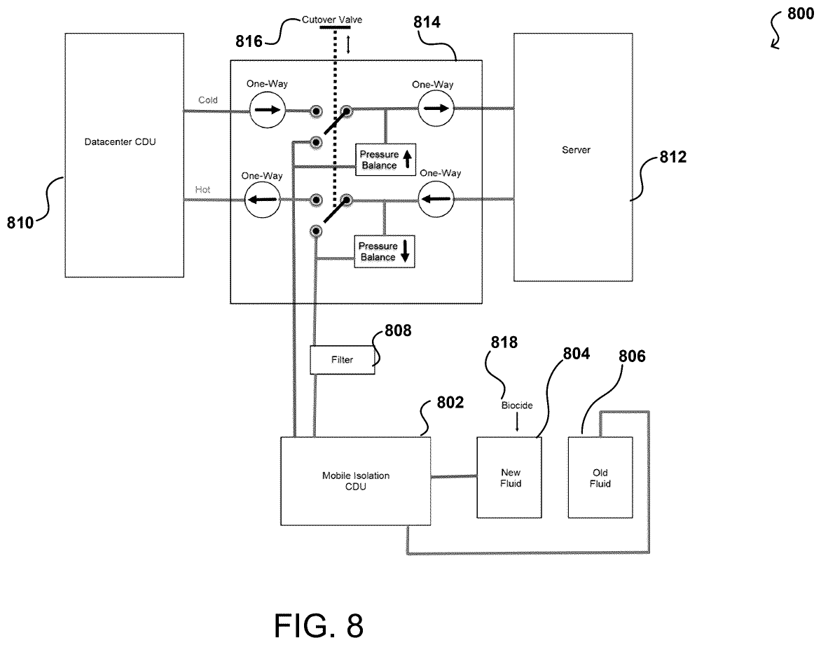

FIG. 8 illustrates an example configuration 800 where new fluid can be injected into the system using a secondary cooling loop and a mobile isolation CDU 802, otherwise referred to as a secondary CDU, to replace the liquid coolant present in the at least one cooling loop. The mobile isolation CDU 802 may include a unit housing which can be connected to a source 804 of new fluid. As illustrated in FIG. 8, biocide 818 may be added to the new fluid to help clean the lines of the cooling loop in the server 812 and other such components. The old fluid previously in those lines can be filtered using at least one filter 808 to remove particulates and/or contaminants in the fluid, such as biological material that was displaced or modified by the biocide 818. The filtered fluid can then be directed by the mobile isolation CDU 802 to an old fluid reservoir 806 or other such location. The old fluid may then be cleaned, modified, reused, or discarded as appropriate.

In many instances, such a mobile isolation CDU 802 or a secondary CDU can be used in response to a detected failure or when routine maintenance is needed. In at least some embodiments, a monitoring system can attempt to predict when an issue might occur and attempt to take (or recommend) preventative action. One or more sensors can monitor aspects of the cooling system and networked devices, and can generate alarms or notifications when it is determined that the cooling fluid may need to be replaced, a server 812 may need to be isolated, etc. Such a system can also potentially detect or predict a fluid leak or failure from a primary CDU or data center CDU 810, and can recommend switching over to a secondary cooling loop, which in some embodiments may require use of multiple mobile CDUs for different racks or rows of servers. A mobile isolation CDU 802 or other secondary CDU can thus also be used as a backup CDU in case a primary CDU or data center CDU 810 has an issue or needs to be taken offline, allowing for at least the most critical servers in the data center to continue uninterrupted operation. In some systems, cutover valves can be automatic and can be used to automatically switch between cooling loops in at least some situations or under some designated criteria.

In one example use case, mobile CDUs can be used to keep at least a server 812 or certain racks of servers running in a data center in the event that maintenance needs to be performed on a primary data center CDU 810. In at least one embodiment, it can be desirable to have the fluid in the secondary cooling loop have properties similar to that of the fluid in the primary loop, in order to have similar properties regarding at least heat removal. Such an approach can allow the primary or main data center CDU 810 to be taken offline without taking all, if any, of the servers offline as well. The server 812 or racks of servers can then be switched back to the primary cooling loop after maintenance is complete and the primary data center CDU 810 is back online. In at least one embodiment, such maintenance can be performed without any of the server 812 or racks of servers being able to detect any change or variation in operating conditions. A mobile isolation CDU 802 or secondary CDU can also be part of a server “crash cart” in at least one embodiment, where a mobile unit can be moved near a server to provide various components or devices that can be connected to a server, such as a source of power, a video cable with a monitor, interface connectors for attaching input mechanisms or control devices, and the like.

In some embodiments, a mobile isolation CDU 802 can be used as a source of redundancy for a high importance server 812 or racks of servers. For example, a mobile isolation CDU 802, otherwise referred to as a secondary CDU, could be dedicated to (or even incorporated in) a server or rack of servers. In the event of a detected failure in a primary CDU or data center CDU 810, for example, the mobile isolation CDU 802 or secondary CDU could be used to ensure sufficient coolant flow to the servers of the rack. In at least one embodiment, a cutover manifold 814 may be used that includes one or more automated cutover valves 816, such that the cutover can occur whether or not a human technician is available to quickly turn one or more manual cutover valves 816, which can further help to avoid issues with changes in flow. Sensors can be used to detect issues such as coolant leaks or low flow, as discussed elsewhere herein, and a manual cutover can be performed as appropriate. In at least one embodiment, a secondary flow of coolant may be used to supplement a primary flow if the flow rate or pressure drops and coolant from the secondary flow may not itself be sufficient to replace the entire flow. A cutover valve 816 can also include backflow prevention so that multiple CDUs can be operated concurrently. In example embodiments, the flow of liquid coolant is able to be concurrently provided by the primary CDU or data center CDU 810 and the secondary CDU or mobile isolation CDU 802. Excess flow may also be used where it is necessary to provide extra heat removal over a period of time, even if that additional flow may exceed determined limits and may reduce the operational lifetime of one or more components involved, but where such reduction may be preferable to issues that may be triggered if sufficient heat removal is not performed over a period of time.

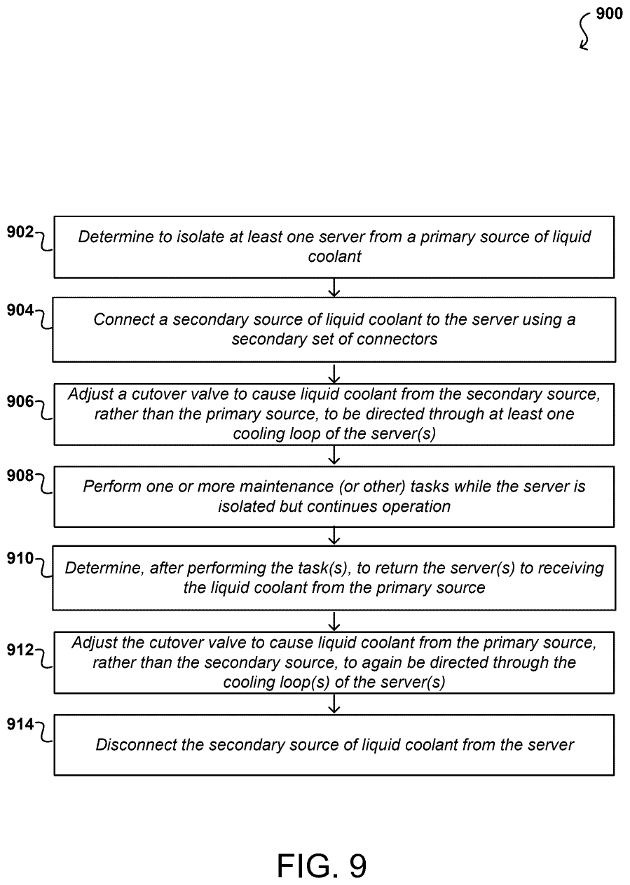

FIG. 9 illustrates an example process 900 that can be performed to allow for cutover between flow of a cooling liquid, a primary CDU such as a data center CDU, and a secondary CDU such as a mobile CDU, according to at least one embodiment. It should be understood that for this and other processes presented herein that there may be additional, fewer, or alternative steps performed or similar or alternative orders, or at least partially in parallel, within the scope of the various embodiments unless otherwise specifically stated. Further, although this and other examples herein will be discussed with respect to coolant flow for servers and related components, there can be other types of operational systems that can benefit from advantages of such a process as well, within the scope of various embodiments. In this example, it is determined 902 to isolate at least one server from a primary source of liquid coolant, such as a primary data center CDU. This isolation may be for any of a number of reasons, such as to perform maintenance on the server or CDU, to clean or replace coolant, or to provide for additional cooling capacity, among other such options. A secondary source of liquid coolant, such as a mobile CDU, can be connected 904 to the server using a secondary set of connectors. In at least one embodiment, a first set of connectors for the primary CDU and the secondary set of connectors for the secondary CDU or mobile CDU can be connected to a cutover manifold, where the cutover manifold is connected directly to the inlet and outlet ports of a cooling loop through the server or other electronic components.

Once connected, a cutover valve can be adjusted 906 (manually or automatically) to cause liquid coolant from the secondary source or mobile CDU, rather than from the primary source or CDU, to be directed through at least one cooling loop of the server(s) connected to the cutover manifold. This cutover can occur without a need to power down any of the servers, allowing for various maintenance or other tasks to be performed with zero downtime of the impacted servers. One or more of these maintenance (or other such tasks) can be performed 908 while the server(s) is isolated from the primary CDU and continues operation. In example embodiments, the transition from a primary CDU to the secondary CDU or mobile CDU may occur without impacting operational availability of the server or other connected computing devices. After performing the task(s), it can be determined 910 to return the server(s) to receiving liquid coolant from the primary source or CDU. The cutover valve can again be adjusted 912 to cause liquid coolant from the primary source or CDU, rather than the secondary source or CDU, to be directed through the cooling loop(s) of the impacted server(s). The secondary source of liquid coolant may then be disconnected 914 from the server, which for a mobile isolation CDU, otherwise referred to as a secondary CDU, allows the mobile isolation CDU to be moved near another server, rack, cluster, or row for which isolation is to be performed. As mentioned, such an approach can be used to introduce a biocide into the cooling system or replace fluid in the cooling system, among other such options. In example embodiments, the flow of liquid coolant provided by the secondary CDU or mobile CDU may replace or clean the fluid present in the cooling loop(s). In example embodiments, the flow of liquid coolant is able to be concurrently provided by the primary CDU and the secondary CDU or mobile CDU.

In various cooling systems, one or more cooling loops (and heat removal components of those cooling loops) will pass near or through various heat-generating components. In at least some embodiments, a cold plate (or other component of a cooling system) may be thermally connected to a heat-generating component, such as by using a paste, material, adhesive, or other such connection mechanism. This may take the form of a layer, patch, or other instance of thermal interface material (TIM) positioned between the cold plate and the heat-generating component, such as a processing unit. Generally speaking, a TIM can refer to any material that is inserted between two or more components in order to enhance the thermal coupling between the components.

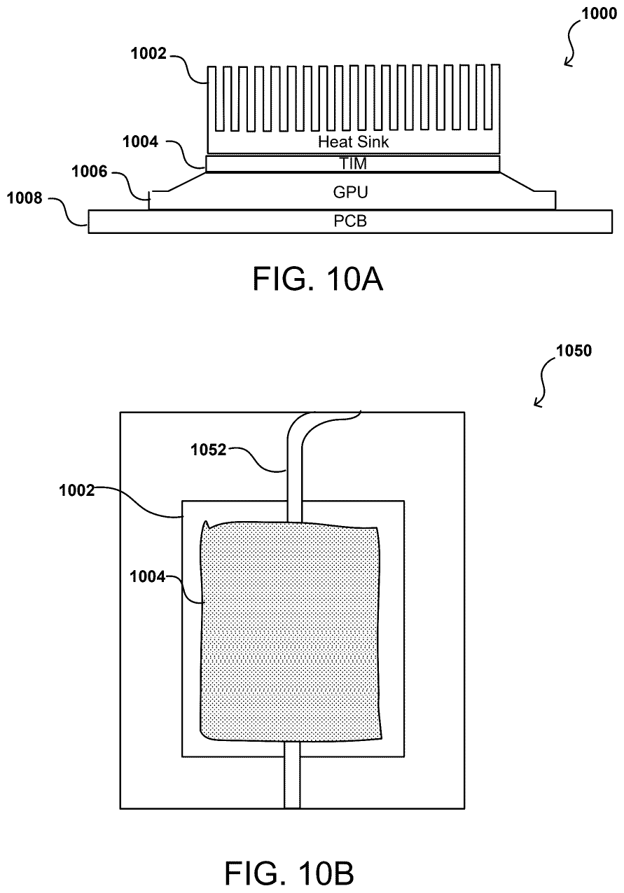

FIG. 10A illustrates an example assembly 1000 that includes such a TIM thermally connecting two components in accordance with at least one embodiment. In this example, the assembly includes a number of components positioned on a printed circuit board (PCB) 1008, although other embodiments may include other suitable components not illustrated herein. At least one graphics processing unit (GPU) 1006 is positioned on the PCB 1008 and connected to circuitry to allow data to be transmitted to and from the GPU 1006. Components such as a GPU 1006 may generate a significant amount of heat, and it may be desirable to remove or dissipate this heat to prevent performance (or other such) issues with the GPU 1006 or related components. Accordingly, a heat sink 1002 (such as a cold plate of a liquid cooling system) can be positioned relative to the GPU 1006 such that heat from the GPU 1006 can be transferred to the heat sink 1002 (or cold plate, etc.) and then dissipated or exchanged as appropriate. In other example embodiments, the heat sink 1002 may be positioned relative to any other suitable heat-generating components, such as the processing unit of a computer system.

In many such assemblies, if a heat sink 1002 such as a cold plate were to be placed directly on top of (or otherwise adjacent to) a heat-generating component, such as a GPU 1006 or chip, then a thin layer of air gaps would exist between the two mating surfaces. These gaps are a result of the imperfection and/or roughness of those surfaces. Such air gaps can function as thermal barriers to heat dissipation, reducing the ability for the heat sink 1002 to efficiently remove heat from the GPU 1006. Accordingly, many such assemblies will use a layer (e.g., a patch) of a thermal interface material (TIM) 1004 between the heat sink 1002 (or cold plate) and the heat-generating component, which is the GPU 1006 in this example. The TIM 1004 can be used to remove or reduce the presence of air gaps, thereby reducing the presence of these thermal barriers. The TIM 1004 can be selected to have high thermal conductivity, in addition to the ability to fill in these micro air gaps, to allow for significant heat transfer from the GPU 1006 to the heat sink 1002. In example embodiments, the TIM 1004 may be selected to minimize a presence of air gaps or thermal barriers between the one or more cold plates or heat sinks 1002 and the one or more GPUs 1006 or other heat-generating components that would otherwise reduce heat transferability. The TIM 1004 can also be selected such that it will not degrade or present a reduction in these properties over time. Examples of thermal interface materials include thermal tapes, gap filler pads, thermal greases, phase change materials, thermal epoxies, gels, and solders, among other such options.

In the example assembly 1000 of FIG. 10A, a layer of thermal tape is used to form a patch of TIM 1004. Such a tape patch can include a thermally-conductive, double-sided adhesive tape that is able to hold the heat sink in place with respect to the GPU without a separate mechanical attachment, and maintain that attachment at high temperatures and through thermal cycling. Other TIM components or layers can be used as well, as may correspond to gap filler pads or elastomeric pads, among other such options. An example layer of TIM for such purposes can be approximately 0.25-2.0 mm in thickness, with a width and length corresponding to the heat sink 1002 and GPU 1006 to be thermally attached, such as may include ranges between 2.0 mm and 10.0 cm. In order to ensure at least a minimum amount of heat transfer, or an amount of heat transfer within a target range, the patch of TIM 1004 to be used may be of a determined size and shape, such as may cover a determined percentage or area of the mating surfaces. The position of the TIM 1004 may also be important to ensure sufficient attachment strength and thermal conductivity between those mating surfaces. Since the TIM 1004 may be applied to at least one of the mating surfaces using an automated (or manual) process in a production line, it can be desirable to ensure that the TIM 1004 does also not include an anomaly (e.g., irregular shape, etc.) that may result in variations in thermal conductivity across the dimensions (e.g., width, etc.) of the TIM 1004. The TIM may be applied manually by a human operator or automatically by an automated mechanism, or a combination thereof. In the view 1050 of FIG. 10B, which is a bottom view with the GPU not shown, a TIM 1004 is illustrated as connected to the heat sink 1002 or cold plate. For a liquid-cooled embodiment, there may be tubing 1052 (e.g., copper tubing) running into, and out of, a heat-sink 1002 or cold plate in order to pass a flow of liquid that, under normal operation, would serve to remove heat from the GPU, where the heat would transfer through the TIM 1004 to the heat sink 1002 or cold plate.

In high performance computing situations, the performance of such a TIM can be critical to appropriately cooling a chip or processor. The thermal performance of a TIM can depend in part upon the quality of the curing process that was used. Some TIM materials require a curing process where the materials are held at a specific temperature for an extended period of time. The temperature and length of time can be critical to ensure that a TIM, after curing exhibits, the appropriate thermal characteristics. A TIM often requires a cure process that requires the material to be held at a specific temperature for a specific length of time. This can be accomplished by baking the full system in an oven. With large systems such as rack mounted servers, however, baking the whole unit is challenging as some of the plastics may not survive the curing process. In order to help expedite the curing process, avoid component overheating, and reduce the cost of providing and maintaining separate equipment, a TIM curing process can also be performed on the manufacturing line itself. At least one current approach involves applying a load to a heat-generating component, such as a GPU, in order to cure a TIM connected to the GPU. Such an approach is not foolproof, however, as it requires precise tuning to get the load power correct, particularly as any significant changes in manufacturing conditions can cause the test to need to be re-tuned or as external factors may impact the temperature of the liquid as it passes through a cooling loop, etc. Manufacturing facilities sometimes have difficulty controlling the internal environment, which can result in large batches of units having to be re-baked, or re-cured, and can also result in device failure in the field due in part to improper curing of one or more TIMs, which can be exacerbated when all TIMs cured concurrently had an incorrect temperature applied, or had such temperature applied inconsistently or for an incorrect period of time.

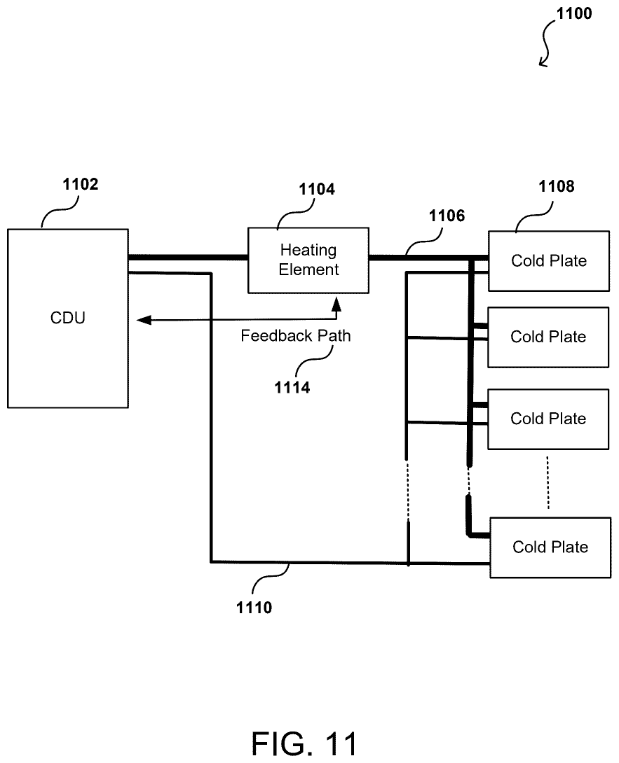

Approaches in accordance with at least one embodiment can provide for curing of one or more TIMs during a manufacturing process, or on a manufacturing line. FIG. 11 illustrates one example system 1100 that can be used to cure instances of a TIM according to at least one embodiment. Instead of applying a load to a heat-generating component, such as a processor, however, heat can be applied using the liquid or fluid (e.g., water or coolant) flowing through the cooling system, such as through one or more cold plates 1108. A coolant distribution unit (CDU) 1102 or other such component of a cooling system can provide a flow of liquid through at least one cooling loop including an inlet loop 1110 and an outlet loop 1106. A heating element 1104 (such as a tankless heater, electronic heating element, or other such heating mechanism) can apply a thermal load to the flow of liquid from the CDU before the liquid reaches the first cold plate 1108. In example embodiments, the heating mechanism generates the heat according to a dynamic programmable load. In example embodiments, a dynamic programmable load may refer to a curing process for TIMs that involves actively adjusting and maintaining the temperature of the curing medium throughout the curing period. This approach may involve varying the temperature of the heated liquid flow in response to specific parameters, such as the thermal characteristics of the TIM being cured, ambient conditions, or even changes in heat generation during different phases of curing. As a nonlimiting example, if the system detects that the TIM requires a higher curing temperature due to its specific thermal characteristics, the programmable load can adjust by increasing the output of the heating element to raise the temperature accordingly. Conversely, if ambient conditions change—such as an increase in room temperature—the system can dynamically reduce the heating output to prevent overheating. This real-time adjustment allows for precise control over the curing process, ensuring that each TIM patch is cured effectively regardless of external variations. In another example embodiment, operators could input specific parameters related to different types of TIMs being used across various components within multiple servers. The programmable load would then automatically adjust based on these inputs and ongoing feedback from temperature sensors throughout the curing period. If one type of TIM requires a gradual ramp-up in temperature followed by a sustained period at peak heat before cooling down, the dynamic programmable load can execute this tailored profile automatically.

The temperature of the liquid can be heated to a desired temperature, and flowed through the cold plates for a sufficient amount of time at that temperature in order to cure the TIM. It should be understood that other curing or similar processes might not require constant temperature but temperature that varies according to a temperature curve over a period of time, and the heating element 1104 can be controlled to adjust the temperature of the liquid over that period of time according to the determined temperature curve. For example, a heating element could heat the liquid to 85 degrees C. over an initial heating period, hold the temperature at 85 degrees C. for 45 minutes, then cool the liquid back down over a cooling period, which should provide for adequate curing of an example TIM. Each TIM may have its own distinct temperature curve and/or curing requirements, as may be based upon factors such as the type of material, thickness of the material, and the like. For example, some TIMs may cure closer to 60 degrees C., while others may cure closer to 100 degrees C., among other potential temperatures and ranges. In some embodiments, the curing temperature of these phase-changing TIMs in such an approach may be limited by the operating range of the electronic components of the underlying system. A library of temperature requirements or curing profiles can be maintained for the various TIMs that may be used in a given manufacturing facility, and used as appropriate for a current type of system being manufactured.

An advantage to such an approach, other than being more controllable and stable than a processor load-based curing approach, is that such an approach is system agnostic, and can be used with any components able to have sufficient heat applied by one or more flows of heated liquid in a cooling loop, or other such flow mechanism or pattern. A heating element or device such as a gas-powered, tankless water heater can be used to quickly and precisely adjust and maintain the temperature of the fluid passing through the cooling loop.

Another advantage to such an approach is that the TIMs can be cured without the underlying electronic system being powered up or operational. The heated liquid can be passed through the relevant cold plates 1108 independent of whether the electronic components to which those cold plates are connected by a TIM are powered up or not. In fact, for precise temperature control, it can be advantageous to perform the curing when no power or load is applied to the electronic components, so that no additional heat is generated that could potentially exceed an operational bound or parameter. Such an approach also allows for the curing of multiple TIMs concurrently, as long as they all rely on the same thermal profile and the respective cold plates are part of the same cooling loop or system.

In at least one embodiment, a dynamic programmable load can be applied to a heating element 1104 to raise the liquid passing through (or near) the heating element 1104 to be heated to a specific temperature or within a tight band of temperatures. In example embodiments, the heating element 1104 may increase the temperature of the liquid passing through or near the heating element 1104 to a target temperature for a specific time period including, without limitation, thirty minutes, although in other embodiments the time period may be significantly lower or higher. In some example embodiments, this time period may be customizable based on one or more factors including without limitation a targeted curing implementation. The target temperature may be a constant temperature or a varying temperature according to, without limitation, a specified temperature profile. In example embodiments, the target temperature may be based on the temperature profile of the one or more TIM attached to the cold plates 1108. In example embodiments, a heating element 1104 can heat the water flowing through a cooling loop, while a CDU can perform tasks such as to remove the added heat from the liquid as well as to pump the liquid through the cooling loop. In example embodiments, the cooling loop may provide the flow of liquid without an increase in temperature from the heating element 1104 in order to remove heat from the CDU 1102 or other heat-generating components during operation of the system in operation. In effect, the cooling loop is designed to ensure that there is no further increase in temperature as it passes through. Instead, the cooling loop effectively cools down and removes heat from the CDU 1102 or other heat-generating components during system operation. A feedback path 1114 can be positioned between the CDU 1102 and the heating element 1104, where the feedback can be used to adjust, control, or maintain the liquid temperature, particularly where varying temperature over a precise temperature curve is desired or necessary. In some embodiments, there may be different phases of heating, as may include prebake, bake time, and cooldown, among other such options, which may be used to limit shock and stress to components during significant changes in applied heat. Using a cooling loop in such a way avoids the need to tune the underlying electronic systems, and allows for a much more consistent resulting temperature (or temperature curve) for the attached cold plates. Additionally, because the loop is agnostic of the underlying electronic system, multiple cold plates can be cured simultaneously. In the loop, it can be seen that the heated liquid is directed to the cold plates in parallel, instead of in series, such that the water flowing into each of the cold plates should be at approximately the same target temperature resulting from application of the heating element 1104. The target temperature may be a constant temperature or a varying temperature according to, without limitation, a specified temperature profile. Instead of being passed through another cold plate (or heat sink, etc.), the liquid coming out of each cold plate (after use in curing a TIM) can be directed to the CDU for cooling, pumping, or other processing.

In at least one embodiment, the quality of the curing can be evaluated at a later time, using the same system or a separate system. This can include, for example, performing thermal testing in the manufacturing flow to determine whether the TIM was cured properly and demonstrates the appropriate thermal characteristics. In one example, one or more thermal sensors or temperature sensors on a die can be used to determine and/or monitor heat transfer between the die and a cold plate thermally connected by an intermediate TIM. If the amount of heat transfer is determined to be within a target range, then it can be determined that the TIM was cured properly. If the amount of heat transfer (or other thermal characteristic) is not within an expected range, then it can be determined that there may be an issue with the curing of the TIM, placement of the TIM, or another such issue that may be worth investigating. For example, if a die is known to produce a certain amount of heat, then cooled liquid passing through the cooling loop, at a controlled temperature and flow rate, should remove a certain amount of heat from the die and cause the die to operate within an expected temperature range. If the die is found to operate at a higher temperature, then it can be determined that there is an issue impacting heat removal, and the die may be removed from operation, or prevented from being placed into operation on live data, until investigation is performed or another such action is taken. In example embodiments, the thermal sensors or temperature sensors may monitor a temperature of the liquid in the cooling loop and provide temperature data to the heating element 1104 or other heating mechanism to allow for maintenance over a specified period of time. In example embodiments, the heating mechanism generates the heat according to a dynamic programmable load. Early detection of such issues can help prevent components from being placed into operational systems which might present a potential hazard due to, for example, a damaged, missing, or incorrectly installed component. Being able to identify potential issues before a component is used on live data can help to better achieve zero downtime, as there will be no need to later remove that component from operating on live data due to those issues.

As mentioned, a cooling loop (or other flow of liquid) may be used to concurrently cure a number of TIMs. This can include multiple TIMs, in a server, server rack, or row of servers in a data center, among other such options. There may be practical limits on the size of the cooling loop or number of components included. For example, longer runs of cooling tubing can make it difficult to maintain the liquid at a specific temperature. Further, heating a large number of cold plates at the same time can create temperature variations across a facility that may have negative impact on other components operating in that facility. In some embodiments, thermal modeling can be used to determine a maximum size of a cooling loop, or number of cooling components, that can be used concurrently in a given space while maintaining in a desired acceptable thermal state.

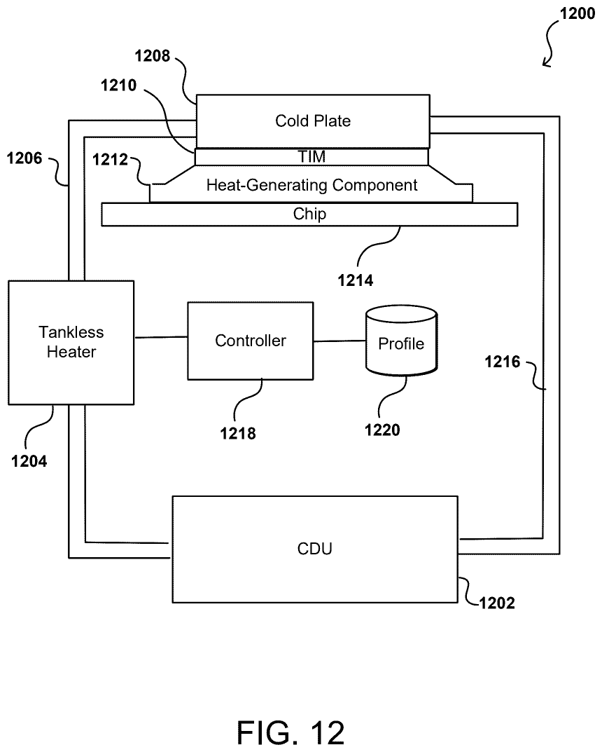

FIG. 12 illustrates an example curing system that can be used in accordance with at least one embodiment. In this example, a layer of thermal material such as a TIM 1210 is used to thermally connect a heat-generating component 1212, such as a processing unit of a computer system, with a cold plate 1208 that can be used to remove heat from the heat-generating component 1212. In example embodiments, the TIM 1210 is selected to minimize a presence of air gaps or thermal barriers between the cold plate 1208 and the heat-generating component, such as the tankless heater 1204, that could reduce heat transfer ability. The TIM 1210 may include, without limitation, thermal tape, gap filler pad, thermal grease, phase change material, thermal epoxy, gel, or solder. In this example, the heat-generating component 1212 is mounted on a chip 1214 as part of a system on chip (SoC) device. The CDU 1202, in this example, can direct a flow of fluid through inlet piping 1206 as part of a cooling loop that passes through the cold plate 1208. A heating element such as a tankless heater 1204, in this example, can apply a determined amount of heat to the fluid in the inlet piping 1206 to cause that fluid to be at a desired temperature for a period of time. In example embodiments, the heating element, such as the tankless heater 1204, may generate heat according to a dynamic programmable load. The heated fluid, when passed through the cold plate 1208 (which is made of a metal or other material that conducts heat) can cause the TIM 1210 to also be raised to approximately the temperature of the fluid passing through the cold plate 1208. Causing the TIM to be at a target temperature for a target period of time can allow for curing of the TIM, allowing for a change in phase that will result in specific thermal properties of the TIM that will allow heat from the heat-generating component 1212 to be passed to the fluid flowing through the cold plate 1208 during operation of the heat-generating element, and when the CDU 1202 is being used to cool the heat-generating element (and potentially other elements associated with the cooling loop). In example embodiments, the tankless heater 1204 or some other heating element may increase the temperature of the liquid passing through or near the tankless heater 1204 to a target temperature for a specific time period. The target temperature may be a constant temperature or a varying temperature according to, without limitation, a specified temperature profile, such as a curing profile for the TIM 1210 to cause the TIM 1210 to have one or more target thermal properties to control how heat is subsequently transferred between the cold plate 1208 and the heat-generating component 1212. In this example, the heated fluid can be passed through outlet piping 1216 and directed back to the CDU 1202, which can remove the excess temperature from the fluid, either alone or in conjunction with a heat exchanger or other such element. In at least one embodiment, a heat exchanger can offload the heat into a larger liquid-and/or air-based system as appropriate. And, as mentioned, there may be multiple cold plates 1208 that receive the flow of fluid through the cooling loop, as may include cold plates on the same board, different boards, different servers, different racks, different rows of racks, and so on. In this example, a controller 1218 (as may comprise a client device) can select the appropriate curing profile from a profile repository 1220, for example, and can cause the tankless heater 1204 to apply heat to the fluid according to the determined curing profile. Such a system may also be used for failure simulation or testing, for example, where the controller 1218 can cause the tankless heater 1204 to increase the temperature of the fluid to flow through the cold plate 1208, and a determination can be made as to how the computing system including the heat-generating element reacts to the change in temperature, such as to see if temperature-related safety features are correctly triggered or other remedial actions are taken, such as whether an appropriate alert is generated and sent to the correct location, address, or recipient. In other example embodiments, the system 1200 may include one or more thermal sensors or temperature sensors that may monitor a temperature of the liquid in either or both the inlet piping 1206 and the outlet piping 1216 and provide temperature data to the controller 1218 to allow for maintenance of the at least one target temperature over a specified period of time. In other example embodiments, the cooling loop may provide the flow of liquid without an increase in temperature from the heating element, such as the tankless heater 1204, in order to remove heat from the heat-generating component 1212 during operation of the system.

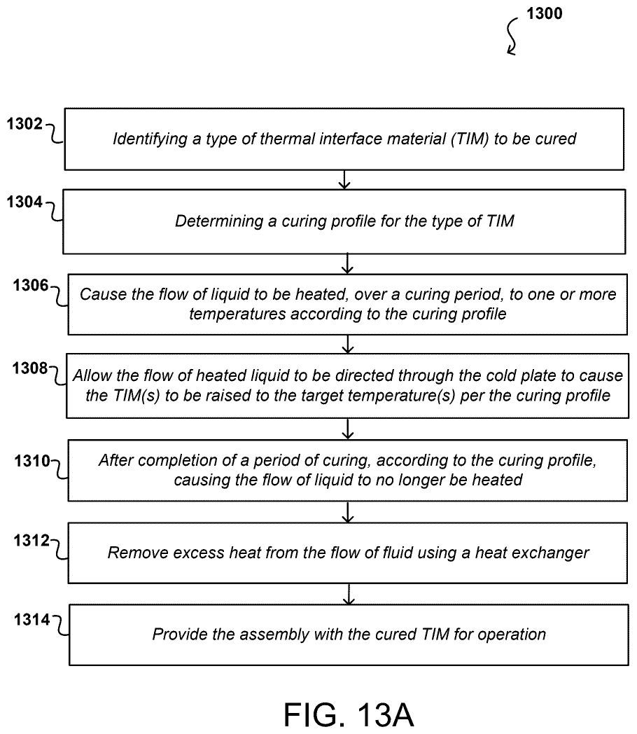

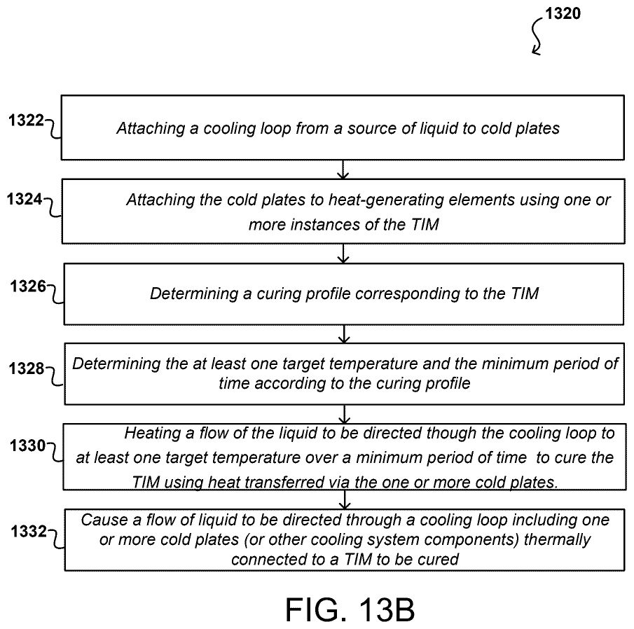

FIG. 13A illustrates an example process 1300 that can be performed to cure a TIM, or other such thermal element, according to at least one embodiment. In this example process, a type of thermal interface material (TIM) is identified 1302 that is to be cured. The type may include not only the type of material, but also the size and thickness of the layer, patch, tape, or other instance of the TIM, which can impact the parameters of the appropriate curing process. A curing profile can be determined 1304 or identified for the type of TIM, where that curing profile may indicate periods of controlled temperature increase, maintenance, decrease, or other variation. A flow of liquid can be caused 1306 to be directed through a cooling loop, including one or more cold plates (or other cooling system components) thermally connected to one or more TIMs to be cured. If multiple TIMs are to be cured concurrently using the same flow, then those TIMs should be of the same or similar types. The flow of liquid can be caused 1308 to be heated, such as by using a heating element on the flow from the CDU before entering a portion of a cooling loop associated with any TIMs. The liquid can be heated over a curing period, to one or more temperatures according to the curing profile, such as to increase the temperature to a target temperature over an initial period, then maintain the temperature over a curing period, etc. The target temperature may be a constant temperature or a varying temperature according to, without limitation, a specified temperature profile. The flow of heated liquid can be allowed 1310 to be directed through the cold plate(s) to cause the thermally connected TIMs to be raised to the target temperature(s) during the curing per the curing profile. After completion of the period of curing, and any subsequent period of decreasing temperature if part of the profile, the flow of liquid can be caused 1312 to no longer be heated. Any excess heat can be removed 1314 from the cooling system using a heat exchanger or other such mechanism. The assembly with the cured TIM can then be provided for operation. The heating and curing in this example occur without power supplied to the connected heat-generating components in order to avoid damage to the components and also to allow for more accurate curing temperature control. Such an approach provides advantages of curing in system, without baking the whole system, and without the downside of needing to tune workloads on a per-setup basis. Consistency of a curing process can be dramatically improved with respect to prior processes, such as those that had dependencies on the operational load of a curing system. Such consistency allows for faster and more reliable scaling of manufacturing operations and improves the resilience of the TIM cure process to external factors, such as factory conditions, weather, and system performance changes, among other such factors.

FIG. 13B illustrates an example process 1320 that can be performed to cure a TIM, or other such thermal element, according to at least one embodiment. In this example process, a cooling loop is attached 1322 from a source of liquid to one or more cold plates. In example embodiments, the cooling loop may include at least an inlet and outlet loop. The cooling loop may connect without limitation a CDU to one or more heating-generating components, such as processing units of computing system as well as other heat generation elements. The source of liquid may be a CDU or other suitable source. The cooling loop may remove heat from one or more heat generation components during operation of the cooling loop. The cold plates may be attached 1324 by thermally connecting the cold plates to one or more TIMs to be cured. The curing profiles corresponding to the one or more TIMs may be determined 1326. If multiple TIMs are to be cured concurrently using the same flow, then those TIMs may be of the same or similar types. The target temperature and the minimum period of time to reach the target temperature is determined 1328 according to the curing profile. The flow of the liquid to be directed through the cooling loop is heated 1330 to at least one target temperature over a minimum period of time to cure the TIM using the heat transferred from the one or more cold plates. The flow of liquids may be directed 1332 through a cooling loop positioned approximate to the one or more cold plates or other cooling system components, which are thermally connected to the TIMs so that the TIMs are cured. In some example embodiments, the heating of the flow of liquid and curing of the one or more TIM may occur without power being supplied to the one or more heat-generating elements.

In computing environments such as data centers, there may be many different types of heat-generating parts, components, systems, and devices, such as servers, switches, and the like. These various types of components may also have very different cooling and power requirements, as well as very different operational behaviors. Each of these different aspects can potentially have a significant impact on the operation of a data center or other such environment. These various aspects are typically for in a pre-planned data center, from the air flow rates through the racks to the total data center cooling capacity, as well as liquid cooling flow rates, coolant distribution unit (CDU) capacity, and other such concerns. In more dynamic data centers that may change over time, however, it can be necessary to detect and collect information for any relevant changes to ensure continued and proper operation of the data center. As an example, server labs are used for development and/or testing typically have a significant number of trays inserted and removed on a regular basis, with different cooling capacity requirements across the trays. In response to a detected change, an operations management system may take an action, such as without limitation to adjust a flow of coolant through one or more cooling loops to ensure proper cooling for the current number of components, amount of heat being generated, or to generate and send an alert. While humans making the changes can update the information, such an approach is subject to human error and inconsistencies.

Approaches in accordance with various embodiments can automate the collection and reporting of important information relating to changes in a computing environment, such as a data center. This information can be transmitted to an operations control or management system, for example, which can determine whether any adjustments need to be made to one or more operational systems for the data center. In dynamic data centers where units may be added and removed relatively frequently, such an approach can help to reduce the amount of manual tuning needed to account for these and other such changes. As an example, data center operations may need to frequently adjust operation of a data center CDU in response to various equipment changes. These changes also need to occur relatively quickly, to avoid issues with regions of excess heat in the data center. Being able to automate data collection and maintain an up-to-date state of the data center can help to avoid mistakes that can impact goals such as zero downtime, where resources are always available (within operational parameters) to process a given workload and avoid expensive downtime.

In at least one embodiment, verifiable information can be added to each of a set of data center components, where those components are of a type that may impact operation of a data center or other such system, network, or environment. This may include, for example, components that require power, require cooling, require data or processing, among other such aspects. For an environment that uses liquid cooling, each liquid-cooled and/or heat-generating component can have a tag, identifier, or other element attached or associated with it, which allows that information to be gathered automatically. This may include, for example, the application of an externally visible tag that is applied to the component, which can indicate information such as without limitation the expected flow rate, required cooling capacity, and expected pressure needed to produce the flow rate, among other such options. The tag may alternatively indicate some type of identifier that can be used to look up this information. A tag may also be a wireless communication tag, such as without limitation an NFC tag, that can convey this information to a near field communication (NFC) reader (or other such device) within sufficient proximity of the tag.

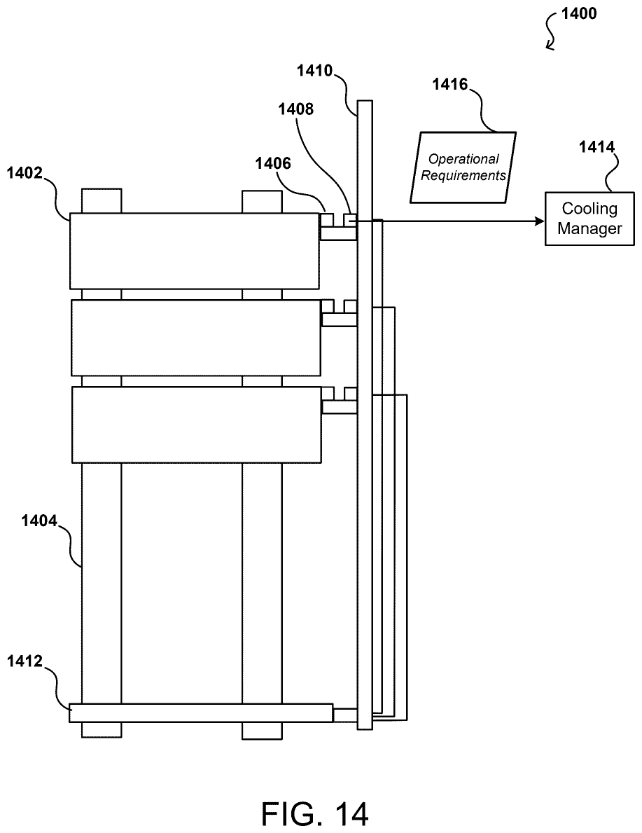

FIG. 14 illustrates an example configuration 1400 allowing for automatic detection of a change in equipment, and determination of any associated changes in operational requirements, according to at least one embodiment. In this example, there are a number of heat-generating components 1402, such as servers in a rack 1404, as well as switches, routers, network interface controllers (NICs), trays, systems on chip, compute resources, and the like. It should be understood that while liquid cooling is used as a primary example, other types of cooling may be used as well, as may relate to airflow and data center air conditioning, among other such options. For a given liquid-cooled rack, the flow rate typically should change whenever one or more trays is inserted into, or removed from, the rack 1404, as each tray and/or component can have its own expected flow rate. As illustrated in FIG. 14, these heat-generating components 1402, which may generate significant amounts of heat during their use, can each have an information tag 1406 attached in a specific location or area on or near the heat-generating component 1402. The tags may include radio frequency identification (RFID) tags, near-field communications (NFC) tags, QR codes, bar codes, identification stickers, physical connections to memory, or Bluetooth transmitters. The location of the tags can be selected so that when a given heat-generating component 1402 is inserted in the rack 1404, the information tag 1406 will be in a position that is able to be read by a nearby tag reader 1408. This can include, for example, a QR code in the form of a sticker applied to the back of a server, which when installed in a rack 1404 will be within the field of view of a camera or imaging sensor. This may also include placement of an NFC tag that can be read by an NFC reader attached to, for example, a cooling manifold 1410 proximate the rack 1404, which is part of the cooling system acting as a source of cooling liquid to direct a flow of cooling liquid through at least one cooling loop for the heat-generating components 1402 and through the computing environment, thereby removing heat from the heat-generating components 1402. A physical connector can also be used, such as a connector that connects to an EEPROM or non-volatile storage device and is able to obtain the relevant information. Physical connectors may be appropriate in locations such as data centers that do not allow use of wireless technologies for such purposes. Other such mechanisms can be used as well within the scope of the various embodiments.

In this example, a user may slide a tray into the rack 1404 where that tray supports a server or other heat-generating component 1402. Various data system components have quick disconnects (or other such connections) on a rear face, and a tag reader 1408 could be placed on, or proximate, the disconnect to communicate information about the component as read from the information tag 1406. The information tag 1406 on the newly-added server can be detected by the respective tag reader 1408, which can capture information from the information tag 1406 and transmit that information to an appropriate operations controller, or other such system or service. Other types of communication can be used as well, as may include CAN, I2C, ethernet, Bluetooth, or other types of communication. The tag readers 1408 may be positioned on a rack 1404 to detect a tag 1406 associated heat-generating component 1402 such as a server placed in a server tray of the rack 1404. In this example, the information collected by the various tag readers 1408 is fed to a rack manager 1412, which can include at least one processor and memory that allows the information to be aggregated from the various readers and the aggregated information (or data derived from the aggregated information) can be sent to a data center operations management system or other such data center infrastructure. A data center operations management system can then analyze that information to determine whether any adjustments are to be made. In example embodiments, the tag readers 1406 may also determine, based on the information received from the tags 1406, cooling requirements for additional heat-generating components 1402 or heat-generating components subsequently installed near the one or more tag readers. In such example embodiments, a cooling manager such as a data center operations manager may determine whether to make adjustments to the source of cooling liquids based on the additional cooling requirements. In other example embodiments, the tag readers 1408 may read one or more power requirements or operating temperature limits for the heat-generating components 1402 from the tags 1406. The cooling manager or data center operations manager may use these power requirements or operating temperature limits to determine whether it should perform additional adjustments to the operation of the computing environment.

For example, a server might be added to a rack 1404, where that server (or some other heat-generating component or heat-generating component) has specific operational requirements 1416, such as cooling requirements and a specific operational range. A cooling manager 1414 or data center operations manager which includes, at the very least, a processor and a memory, can check the current state of the data center to determine whether the current state satisfies those operational requirements 1416 and whether adjustments must be performed with regarding to, without limitation, the source of the liquid based at least in part on the cooling requirements. As a nonlimiting example, the cooling manager 1414 may receive the operational requirements 1416 from the tag reader 1408 in response to the cooling manager 1414 detecting a change in the presence of the tag 1406. The operational requirements 1416 may include, for example, whether the amount of coolant flow through the cooling manifold 1410 for a rack is sufficient to remove the amount of additional heat, and whether the current state of the cooling system falls within the operational range of the newly-added component. If not, one or more adjustments can be identified and automatically propagated to the relevant systems or sub-systems, such as to increase a target flow rate of cooling liquid through relevant cooling loop that will provide heat removal for the newly-added component. Other actions can be taken as well, such as to adjust an expected liquid temperature, or to throw a warning that the rack power exceeds cooling capacity, among other such options. In normal operation, such an approach could reduce the amount of manual work needed to bring the cooling into alignment with expectations. Such an approach can also provide an extra step of safety by allowing the data center to automatically flag potential cooling capacity problems. Similar behaviors could be driven for air-cooled systems as well, as may relate to the data center's expected air flow rate from a cool aisle to a hot aisle, the total cooling capacity, or even data center power, etc. In other example embodiments, the data center operations manager or cooling manager may determine adjustments to be made with respect to the at least one source of air cooling based, at least in part, on the one or more cooling requirements. In other example embodiments, the data center operations manager or cooling manager may generate a warning based on a current value or predicted value of the computing environment with respect to the cooling requirements. For example, the data center operations manager or cooling manager may receive or generate a current or predicted thermal indicator (e.g., air temperature, temperature of the heat-generating component 1402, temperature of the liquid, etc.), and, based on this indicator, generate a warning for the administrator or user of the system. Being able to automatically detect changes and generate alarms for quickly-identified problems can help with goals such as zero downtime, as well as to help avoid larger scale problems that may otherwise result.

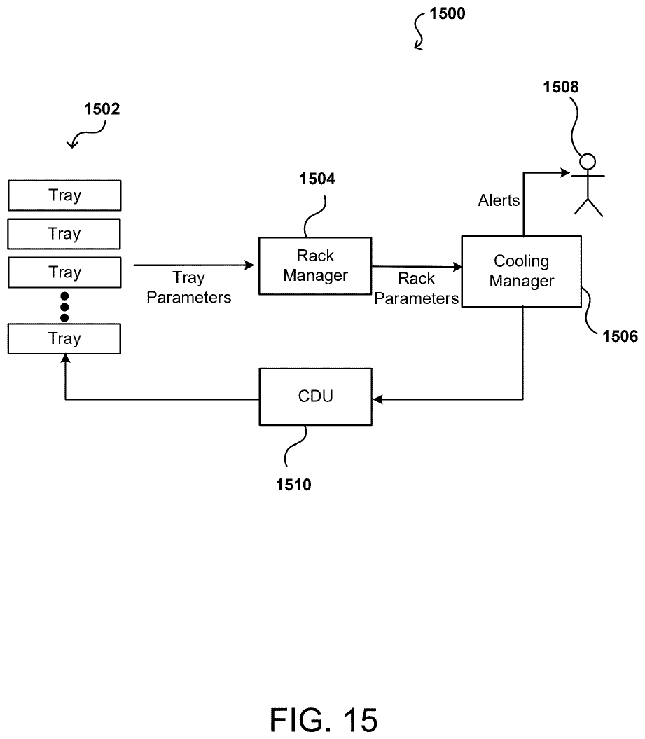

FIG. 15 illustrates an example system 1500 that can be used to adjust operational aspects of a data center, or other such computing environment, according to at least one embodiment. In this example, there are a number of server trays 1502 or other electronic components that may be positioned in one or more racks, or rows of racks, in a data center. Each of these components can have a set of operational requirements or expectations, such as an amount of power and cooling needed, operational temperature ranges, and the like. As mentioned, each of these trays 1502 can have a tag (or other such informational conveyance mechanism) attached that is able to provide at least some of the information about these requirements and/or expectations. In at least one embodiment, when a given tray 1502 is inserted into a rack, at least one tag reader in, on, or associated with the rack can detect the tag and obtain the information from the tag. In at least one embodiment, a rack manager 1504 might have a camera positioned to view the tag for any tray 1502 in a rack, and can pull the information from a captured image, such as may include a QR code or configuration identifier. In another embodiment, there may be a separate tag reader for each tray 1502 location in a rack, such as may be associated with a BNC connector or other quick connect mechanism, or attached to appropriate locations on the rack itself, and the information from those various tag readers can be fed to the rack manager 1504, among other such options. The rack manager 1504 can include at least one processor and memory that allows the rack manager 1504 to analyze (or at least aggregate) the information from the various tags, and provide a current overall set of rack requirements to a cooling manager 1506 which can otherwise be referred to as a data center operations manager. The information may include one or more cooling requirements for the electronic components, liquid-cooled components, or heat-generating components in the trays 1502. This information may be sent periodically, in order to ensure that the correct information is still being used, as well as in response to any change in operational requirements, to make adjustments needed to allow for maintaining the rack in an operational or expected state. If possible, the cooling manager 1506 (or system or infrastructure) can make the appropriate adjustment(s), such as to send instructions to a data center CDU 1510 to increase or decrease a flow of cooling liquid through a cooling loop associated with the trays 1502. If an automatic adjustment is unable to be made by the cooling manager 1506, or if an issue is detected that requires human intervention, then one or more alerts can be generated by the cooling manager 1506 and sent to a data center operator or technician 1508, or other such responsible person or entity. Taking such an approach allows for continued monitoring of operational components of the data center and automated update of various operational parameters in order to maintain the data center operating as expected even as the number, types, and configuration of the components of the data center change over time. By adding additional information to the trays 1502, the cooling manager 1506 (or management system or service, etc.) can be aware of the current expectations for the systems and components being housed there. This allows for automatic adjustments of cooling delivery (liquid or air) using one or more CDUs 1510, for example, without the need for a human in the loop, and adds an additional layer of checks to ensure that the data center does not fall outside the designed limits unexpectedly. The ability to make such automated adjustments can help to ensure zero downtime for the operational components of the data center.

In one example, each server in a data center can have an expected flowrate. One server in a rack may expect one liter per minute, another server might expect five liters per minute, and another might expect three liters of liquid flow per minute. A rack manager 1504 might gather the information from the various tags for those servers in the trays 1502, and may determine that the manifold for the rack now needs to provide flow at a rate of nine liters per minute in order to satisfy the aggregate needs of the servers in that rack. The CDU 1510 providing the flow for the rack can make any adjustments to ensure that the rack is receiving the necessary flow, with the rack manifold and individual cold plates being responsible for ensuring that the correct portions of that flow are delivered to cool the individual servers. For example, individual cold plates may operate at around the same pressure but have different amounts of flow restriction that can control the respective flow through each cold plate, as long as the manifold delivers at around that target pressure. In many situations, there will be an acceptable range of allowed pressures for the various components, and the CDU 1510 will attempt to provide a pressure within the overlap of the pressure ranges for a set of components, typically providing pressure towards a higher end of that range as slightly higher flowrate is typically preferred to slightly lower flowrate. Due to these differences, different types of components may need to be associated with different cooling loops, or only certain groupings of components can be used in a single rack or collection of devices sharing a manifold, etc. If the requirements exceed capacity, such as where ten trays 1502 are plugged into a rack that each requires ten liters per minute of flow, and a respective CDU 1510 or manifold is only rated for 50 liters per minute, then an alert can be generated that the capacity has been exceeded before those components are powered on and generating heat, which might otherwise result in an overheating situation. A data center operator may then decide to move some of the servers to another rack, swap in a CDU 1510 with more capacity, or take another such action. In some embodiments, a cooling manager 1506 might analyze the information for the various components and recommend a different placement of components, such as to move one or more servers to a different rack where the servers have similar requirements in order to conserve energy or resources, or otherwise provide for improved operation of the data center. For example, components with high power requirements might be distributed throughout the data center rather than grouped, in order to attempt to avoid hotspots in the data center that may be oversubscribed on power.

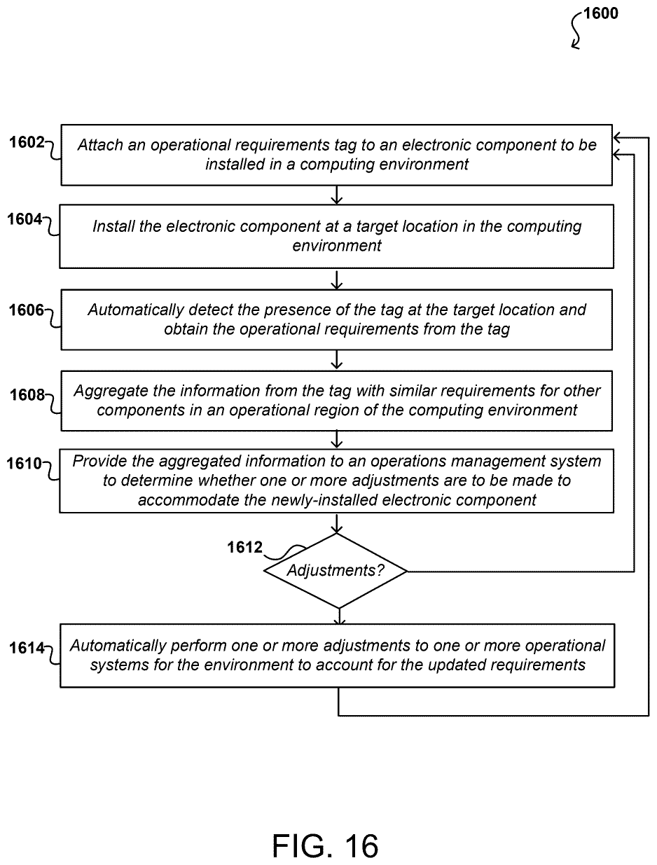

FIG. 16 illustrates an example process 1600 that can be performed to automatically determine updated requirements for a computing environment and make adjustments to account for the updated requirements, according to at least one embodiment. In example embodiments, the actions in the process 1600 may be performed by a processor including one or more logical units configured to perform the actions. In this example, there may be various electronic components (e.g., servers, switches, routers, network interface controllers (NICs), trays, systems on chip, and/or other compute resources) that may be installed into a computing environment, such as a data center or server farm. Many of these components will have operational requirements or expectations, such as an expected coolant flow rate or amount of heat removal, a range of operational temperatures, power requirements, and the like. An operational requirements tag (or other such informational mechanism) can be attached 1602 to a given electronic component that is to be installed in the computing environment, such as in a specific location in a rack in a determined row of a data center. The electronic component can then be installed 1604 in the target location in the computing environment. The tag can be positioned on the electronic component, such as without limitation, a server placed in a server tray on a server rack, such that if the electronic component is installed correctly at the target location, the tag will be readable by at least one tag reader associated with that target location. The tags may include frequency identification (RFID) tags, near-field communications (NFC) tags, QR codes, bar codes, identification stickers, physical connections to memory, or Bluetooth transmitters. The presence of the tag can then be automatically detected 1606 by a tag reader associated with the target location, and the operational requirements can be obtained and/or received from the tag. As mentioned, this might occur through analysis of a QR code captured using a camera or through a transmission of information using NFC or another such wireless communication protocol, among other such options. The information from this tag can be aggregated 1608 with similar requirements for other components in an operational region of the computing environment. An operational region in this context refers to a region of the computing environment, such as a rack or row of server racks that shares cooling, power, or other such resources. The aggregated information can be provided 1610 to an operations management system to determine whether one or more adjustments are to be made to accommodate the newly-installed electronic component. For example, a determination can be made as to whether additional flow of coolant is required for the new component, or whether an operational temperature range needs to be adjusted to avoid overheating the component, among other such options discussed and suggested herein. In other example embodiments, a determination may be made as to whether adjustments with respect to the at least one source of air cooling based should be made. If it is determined 1612 that no adjustments are to be made, then the process can continue with the current operational parameters until another adjustment is made that may require re-evaluation. If it is determined 1612 that one or more adjustments are to be made, then the one or more adjustments can be automatically performed 1614 with respect to one or more operational systems to account for the updated requirements. This may include, for example, adjusting a flow of cooling liquid from a CDU or an amount of power delivered by a power system, among other such options. The process can then continue with the adjusted operational parameters until at least another actionable change is detected.

As mentioned, such a process 1600 can also be performed when a component is removed from a target location. If a component is removed, the tag will no longer be readable by the appropriate tag reader, and the absence of those requirements can be communicated to an operational management system to determine if one or more adjustments can be made to ensure proper operation, and potentially conserve resources. For example, if a server is removed from a rack and not replaced with another component, then it is possible that the flow of coolant through the associated rack can be reduced, which can not only avoid overcooling to ensure proper continued operation with zero downtime, but can also help to conserve resources. There may be instances where an adjustment is not able to be made automatically, such as where the adjustment is not authorized to be made automatically, or where the adjustment requires manual intervention, such as to physically remove a component from a specific location. In these and other such instances, an alert or notification can be generated that can cause a human operator to perform the necessary evaluation, adjustment, or modification, etc. In example embodiments, the process in a process 1600 may generate one or more alerts in response to a current value or a predicted value of the computing environment falling outside the one or more cooling requirements and an automatic adjustment unable to be performed to cause the current value or the predicted value to fall inside the one or more cooling requirements.

In other example embodiments, the tag readers can determine cooling requirements for additional electronic components or heat-generating components subsequently installed near the one or more tag readers. In such example embodiments, a cooling manager such as a data center operations manager may determine whether to make adjustments to the source of cooling liquids based on the additional cooling requirements. In other example embodiments, the tag readers may read one or more power requirements or operating temperature limits from the tags. The cooling manager or data center operations manager may use these power requirements or operating temperature limits to determine whether it should perform additional adjustments to the operation of the computing environment.

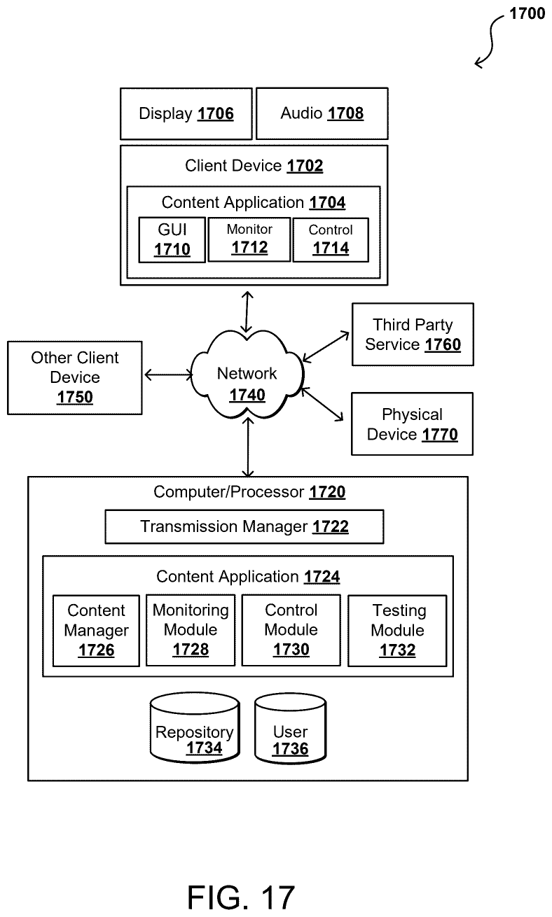

FIG. 17 illustrates an example network configuration 1700 of components that can be used to implement aspects of various embodiments, such as to provide, generate, modify, encode, process, fuse, and/or transmit generated image data, calculated measurements, or other such content. In at least one embodiment, a client device 1702 can generate or receive data for a session using components of a content application 1704 on the client device 1702 and data stored locally on that client device. In at least one embodiment, a content application 1724 executing on a computer or processor 1720 (e.g., a cloud server or control system) may initiate a session associated with at least one client device 1702 (e.g., a vehicle or robot), as may use a session manager and user data stored in a user database 1736, and can cause content such as liquid coolant or server thermal data to be selected and/or retrieved from a repository 1734 to be used by a testing module 1732 to calculate one or more performance metrics for a monitoring module 1728, which can provide flow data or thermal data to a control module 1730 to control a flow or temperature, in an environment where the data is to be used to determine appropriate operation. A content manager 1726 may work with at these various modules to perform testing and analysis, and potentially instruct any actions to be taken in response to a performance metric failing to satisfy an operational requirements. At least a portion of this data or instructional content can be transmitted to the client device 1702 and/or a physical device 1770 using an appropriate transmission manager 1722 to send by download, streaming, or another such transmission channel. An encoder may be used to encode and/or compress at least some of this data before transmitting to the client device 1702. In at least one embodiment, the client device 1702 receiving such content can provide this content to a corresponding content application 1704, which may also or alternatively include a graphical user interface 1710, a flow monitor module 1712, and a control module 1714 for use in providing, synthesizing, rendering, compositing, modifying, or using content for presentation, navigation, control, (or other purposes) on or by the client device 1702, such as may be transmitted to the physical device 1770. In some embodiments, the computer/processor 1720 and client device 1702 may be able to communicate directly without needing to transmit data over a network 1740, in order to avoid issues with latency and availability, etc. A decoder may also be used to decode data received over the network 1740 for presentation via client device 1702, such as imaging content or performance metrics through a display device 1706 and audio, such as corresponding sounds or synthesized speech, through at least one audio playback device 1708, such as speakers or headphones. In at least one embodiment, at least some of this content may already be stored on, rendered on, or accessible to client device 1702 such that transmission over a network 1740 is not required for at least that portion of content, such as where that content (e.g., thermal data) may have been previously downloaded or stored locally on a hard drive or optical disk. In at least one embodiment, a transmission mechanism such as data streaming can be used to transfer this content from the computer/processor 1720, or user database 1736, to the client device 1702. In at least one embodiment, at least a portion of this content can be obtained, enhanced, and/or streamed from another source, such as a third party service 1760 or other client device 1750, that may also include a content application for generating, updating, enhancing, or providing map content. In at least one embodiment, portions of this functionality can be performed using multiple computing devices, or multiple processors within one or more computing devices, such as may include a combination of CPUs and GPUs (Graphics Processing Unit), (DPUs), (QPUs), and a plurality of parallel processing units (PPUs).

In at least some of these examples, client devices can include any appropriate computing devices, as may include a desktop computer, notebook computer, set-top box, streaming device, gaming console, smartphone, tablet computer, VR headset, AR goggles, wearable computer, or a smart television. Each client device can submit a request across at least one wired or wireless network, as may include the Internet, an Ethernet, a local area network (LAN), or a cellular network, among other such options. In this example, these requests can be submitted to an address associated with a cloud provider, who may operate or control one or more electronic resources in a cloud provider environment, such as may include a data center or server farm. In at least one embodiment, the request may be received or processed by at least one edge server, that sits on a network edge and is outside at least one security layer associated with the cloud provider environment. In this way, latency can be reduced by allowing the client devices to interact with servers that are in closer proximity, while also improving security of resources in the cloud provider environment.

In at least one embodiment, such a system can be used for monitoring or managing thermal conditions of a server which includes cold plates as liquid manifolds. In other embodiments, such a system can be used for other purposes, such as for providing control of liquid coolant flow, or for performing deep learning operations. In at least one embodiment, such a system can be implemented using an edge device or may incorporate one or more Virtual Machines (VMs). In at least one embodiment, such a system can be implemented at least partially in a data center or at least partially using cloud computing resources.

### Data Center

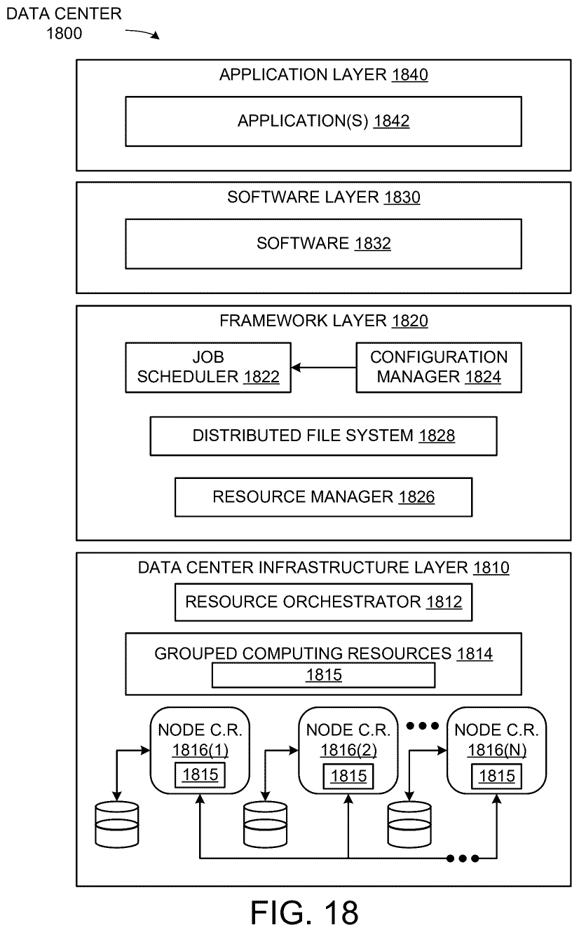

FIG. 18 illustrates an example data center 1800, in which at least one embodiment may be used. In at least one embodiment, data center 1800 includes a data center infrastructure layer 1810, a framework layer 1820, a software layer 1830, and an application layer 1840.

In at least one embodiment, as shown in FIG. 18, data center infrastructure layer 1810 may include a resource orchestrator 1812, grouped computing resources 1814, and node computing resources (“node C.R.s”) 1816(1)-1816(N), where “N” represents a positive integer (which may be a different integer “N” than used in other figures). In at least one embodiment, node C.R.s 1816(1)-1816(N) may include, but are not limited to, any number of central processing units (“CPUs”) or other processors (including accelerators, field programmable gate arrays (FPGAs), graphics processors, etc.), memory storage devices e.g., dynamic read-only memory, solid state storage or disk drives), network input/output (“NW I/O”) devices, network switches, virtual machines (“VMs”), power modules, and cooling modules, etc. In at least one embodiment, one or more node C.R.s from among node C.R.s 1816(1)-1816(N) may be a server having one or more of above-mentioned computing resources.

In at least one embodiment, grouped computing resources 1814 may include separate groupings of node C.R.s housed within one or more racks (not shown), or many racks housed in data centers at various geographical locations (also not shown). In at least one embodiment, separate groupings of node C.R.s within grouped computing resources 1814 may include grouped compute, network, memory or storage resources that may be configured or allocated to support one or more workloads. In at least one embodiment, several node C.R.s including CPUs or processors may grouped within one or more racks to provide compute resources to support one or more workloads. In at least one embodiment, one or more racks may also include any number of power modules, cooling modules, and network switches, in any combination.

In at least one embodiment, resource orchestrator 1812 may configure or otherwise control one or more node C.R.s 1816(1)-1816(N) and/or grouped computing resources 1814. In at least one embodiment, resource orchestrator 1812 may include a software design infrastructure (“SDI”) management entity for data center 1800. In at least one embodiment, resource orchestrator 1812 may include hardware, software or some combination thereof.

In at least one embodiment, as shown in FIG. 18, framework layer 1820 includes a job scheduler 1822, a configuration manager 1824, a resource manager 1826 and a distributed file system 1828. In at least one embodiment, framework layer 1820 may include a framework to support software 1832 of software layer 1830 and/or one or more application(s) 1842 of application layer 1840. In at least one embodiment, software 1832 or application(s) 1842 may respectively include web-based service software or applications, such as those provided by Amazon Web Services, Google Cloud and Microsoft Azure. In at least one embodiment, framework layer 1820 may be, but is not limited to, a type of free and open-source software web application framework such as Apache Spark™ (hereinafter “Spark”) that may use distributed file system 1828 for large-scale data processing (e.g., “big data”). In at least one embodiment, job scheduler 1822 may include a Spark driver to facilitate scheduling of workloads supported by various layers of data center 1800. In at least one embodiment, configuration manager 1824 may be capable of configuring different layers, such as software layer 1830 and framework layer 1820 including Spark and distributed file system 1828 for supporting large-scale data processing. In at least one embodiment, resource manager 1826 may be capable of managing clustered or grouped computing resources mapped to or allocated for support of distributed file system 1828 and job scheduler 1822. In at least one embodiment, clustered or grouped computing resources may include grouped computing resources 1814 at data center infrastructure layer 1810. In at least one embodiment, resource manager 1826 may coordinate with resource orchestrator 1812 to manage these mapped or allocated computing resources.

In at least one embodiment, software 1832 included in software layer 1830 may include software used by at least portions of node C.R.s 1816(1)-1816(N), grouped computing resources 1814, and/or distributed file system 1828 of framework layer 1820. In at least one embodiment, one or more types of software may include, but are not limited to, Internet web page search software, e-mail virus scan software, database software, and streaming video content software.

In at least one embodiment, application(s) 1842 included in application layer 1840 may include one or more types of applications used by at least portions of node C.R.s 1816(1)-1816(N), grouped computing resources 1814, and/or distributed file system 1828 of framework layer 1820. In at least one embodiment, one or more types of applications may include, but are not limited to, any number of a genomics application, a cognitive compute, application and a machine learning application, including training or inferencing software, machine learning framework software (e.g., PyTorch, TensorFlow, Caffe, etc.) or other machine learning applications used in conjunction with one or more embodiments.

In at least one embodiment, any of configuration manager 1824, resource manager 1826, and resource orchestrator 1812 may implement any number and type of self-modifying actions based on any amount and type of data acquired in any technically feasible fashion. In at least one embodiment, self-modifying actions may relieve a data center operator of data center 1800 from making possibly bad configuration decisions and possibly avoiding underused and/or poor performing portions of a data center.

In at least one embodiment, data center 1800 may include tools, services, software or other resources to train one or more machine learning models or predict or infer information using one or more machine learning models according to one or more embodiments described herein. For example, in at least one embodiment, a machine learning model may be trained by calculating weight parameters according to a neural network architecture using software and computing resources described above with respect to data center 1800. In at least one embodiment, trained machine learning models corresponding to one or more neural networks may be used to infer or predict information using resources described above with respect to data center 1800 by using weight parameters calculated through one or more training techniques described herein.

In at least one embodiment, data centers may use CPUs, application-specific integrated circuits (ASICs), GPUs, FPGAs, DPUs, QPUs, a plurality of parallel processing units (PPUs), or other hardware to perform training and/or inferencing using above-described resources. Moreover, one or more software and/or hardware resources described above may be configured as a service to allow users to train or performing inferencing of information, such as image recognition, speech recognition, or other artificial intelligence services.

Inference and/or training logic 1815 are used to perform inferencing and/or training operations associated with one or more embodiments. In at least one embodiment, inference and/or training logic 1815 may be used in system FIG. 18 for inferencing or predicting operations based, at least in part, on weight parameters calculated using neural network training operations, neural network functions and/or architectures, or neural network use cases described herein.

Embodiments presented herein can manage various aspects of an operational management system for a computing environment, as may relate to the cleaning, cutover, or adjustment of one or more cooling or power systems.

### Computer Systems

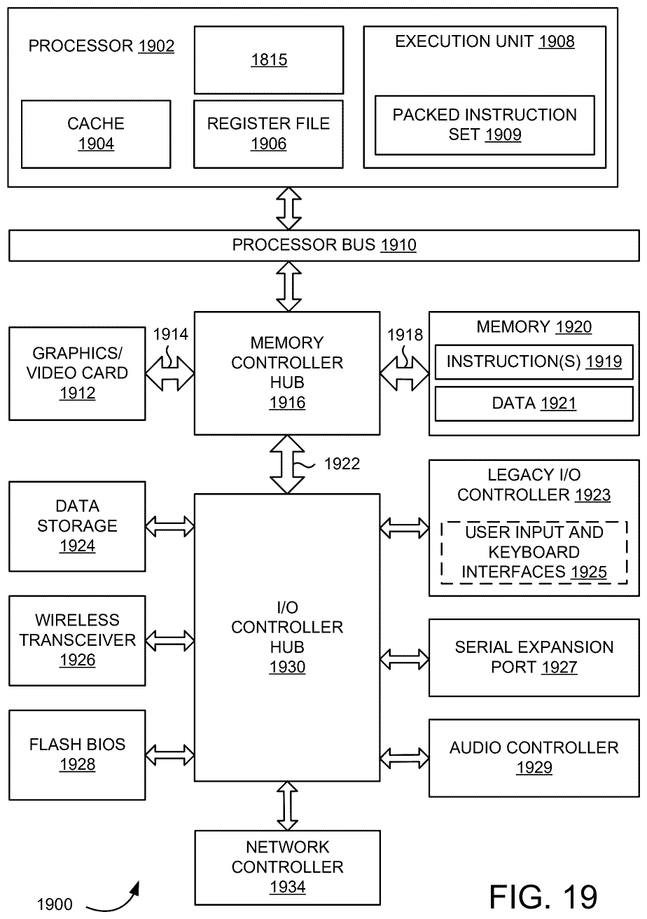

FIG. 19 is a block diagram illustrating an exemplary computer system, which may be a system with interconnected devices and components, a system-on-a-chip (SOC) or some combination thereof formed with a processor that may include execution units to execute an instruction, according to at least one embodiment. In at least one embodiment, a computer system 1900 may include, without limitation, a component, such as a processor 1902 to employ execution units including logic to perform algorithms for process data, in accordance with present disclosure, such as in embodiment described herein. In at least one embodiment, computer system 1900 may include processors, such as PENTIUM® Processor family, Xeon™, Itanium®, XScale™ and/or StrongARM™, Intel® Core™, or Intel® Nervana™ microprocessors available from Intel Corporation of Santa Clara, California, although other systems (including PCs having other microprocessors, engineering workstations, set-top boxes and like) may also be used. In at least one embodiment, computer system 1900 may execute a version of WINDOWS operating system available from Microsoft Corporation of Redmond, Wash., although other operating systems (UNIX and Linux, for example), embedded software, and/or graphical user interfaces, may also be used.

Embodiments may be used in other devices such as handheld devices and embedded applications. Some examples of handheld devices include cellular phones, Internet Protocol devices, digital cameras, personal digital assistants (“PDAs”), and handheld PCs. In at least one embodiment, embedded applications may include a microcontroller, a digital signal processor (“DSP”), system on a chip, network computers (“NetPCs”), set-top boxes, network hubs, wide area network (“WAN”) switches, or any other system that may perform one or more instructions in accordance with at least one embodiment.

In at least one embodiment, computer system 1900 may include, without limitation, processor 1902 that may include, without limitation, one or more execution units 1908 to perform machine learning model training and/or inferencing according to techniques described herein. In at least one embodiment, computer system 1900 is a single processor desktop or server system, but in another embodiment, computer system 1900 may be a multiprocessor system. In at least one embodiment, processor 1902 may include, without limitation, a complex instruction set computer (“CISC”) microprocessor, a reduced instruction set computing (“RISC”) microprocessor, a very long instruction word (“VLIW”) microprocessor, a processor implementing a combination of instruction sets, or any other processor device, such as a digital signal processor, for example. In at least one embodiment, processor 1902 may be coupled to a processor bus 1910 that may transmit data signals between processor 1902 and other components in computer system 1900.

In at least one embodiment, processor 1902 may include, without limitation, a Level 1 (“L1”) internal cache memory (“cache”) 1904. In at least one embodiment, processor 1902 may have a single internal cache or multiple levels of internal cache. In at least one embodiment, cache memory may reside external to processor 1902. Other embodiments may also include a combination of both internal and external caches depending on particular implementation and needs. In at least one embodiment, a register file 1906 may store different types of data in various registers including, without limitation, integer registers, floating point registers, status registers, and an instruction pointer register.

In at least one embodiment, execution unit 1908, including, without limitation, logic to perform integer and floating point operations, also resides in processor 1902. In at least one embodiment, processor 1902 may also include a microcode (“ucode”) read only memory (“ROM”) that stores microcode for certain macro instructions. In at least one embodiment, execution unit 1908 may include logic to handle a packed instruction set 1909. In at least one embodiment, by including packed instruction set 1909 in an instruction set of a general-purpose processor, along with associated circuitry to execute instructions, operations used by many multimedia applications may be performed using packed data in processor 1902. In at least one embodiment, many multimedia applications may be accelerated and executed more efficiently by using a full width of a processor's data bus for performing operations on packed data, which may eliminate a need to transfer smaller units of data across that processor's data bus to perform one or more operations one data element at a time.

In at least one embodiment, execution unit 1908 may also be used in microcontrollers, embedded processors, graphics devices, DSPs, and other types of logic circuits. In at least one embodiment, computer system 1900 may include, without limitation, a memory 1920. In at least one embodiment, memory 1920 may be a Dynamic Random Access Memory (“DRAM”) device, a Static Random Access Memory (“SRAM”) device, a flash memory device, or another memory device. In at least one embodiment, memory 1920 may store instruction(s) 1919 and/or data 1921 represented by data signals that may be executed by processor 1902.

In at least one embodiment, a system logic chip may be coupled to processor bus 1910 and memory 1920. In at least one embodiment, a system logic chip may include, without limitation, a memory controller hub (“MCH”) 1916, and processor 1902 may communicate with MCH 1916 via processor bus 1910. In at least one embodiment, MCH 1916 may provide a high bandwidth memory path 1918 to memory 1920 for instruction and data storage and for storage of graphics commands, data, and textures. In at least one embodiment, MCH 1916 may direct data signals between processor 1902, memory 1920, and other components in computer system 1900 and to bridge data signals between processor bus 1910, memory 1920, and a system I/O interface 1922. In at least one embodiment, a system logic chip may provide a graphics port for coupling to a graphics controller. In at least one embodiment, MCH 1916 may be coupled to memory 1920 through high bandwidth memory path 1918 and a graphics/video card 1912 may be coupled to MCH 1916 through an Accelerated Graphics Port (“AGP”) interconnect 1914.

In at least one embodiment, computer system 1900 may use system I/O interface 1922 as a proprietary hub interface bus to couple MCH 1916 to an I/O controller hub (“ICH”) 1930. In at least one embodiment, ICH 1930 may provide direct connections to some I/O devices via a local I/O bus. In at least one embodiment, a local I/O bus may include, without limitation, a high-speed I/O bus for connecting peripherals to memory 1920, a chipset, and processor 1902. Examples may include, without limitation, an audio controller 1929, a firmware hub (“flash BIOS”) 1928, a wireless transceiver 1926, a data storage 1924, a legacy I/O controller 1923 containing user input and keyboard interfaces 1925, a serial expansion port 1927, such as a Universal Serial Bus (“USB”) port, and a network controller 1934. In at least one embodiment, data storage 1924 may comprise a hard disk drive, a floppy disk drive, a CD-ROM device, a flash memory device, or other mass storage device.

In at least one embodiment, FIG. 19 illustrates a system, which includes interconnected hardware devices or “chips”, whereas in other embodiments, FIG. 19 may illustrate an exemplary SoC. In at least one embodiment, devices illustrated in FIG. 19 may be interconnected with proprietary interconnects, standardized interconnects (e.g., PCIe) or some combination thereof. In at least one embodiment, one or more components of computer system 1900 are interconnected using compute express link (CXL) interconnects.

Inference and/or training logic 1815 are used to perform inferencing and/or training operations associated with one or more embodiments. In at least one embodiment, inference and/or training logic 1815 may be used in system FIG. 19 for inferencing or predicting operations based, at least in part, on weight parameters calculated using neural network training operations, neural network functions and/or architectures, or neural network use cases described herein.

Embodiments presented herein can manage various aspects of an operational management system for a computing environment, as may relate to the cleaning, cutover, or adjustment of one or more cooling or power systems.

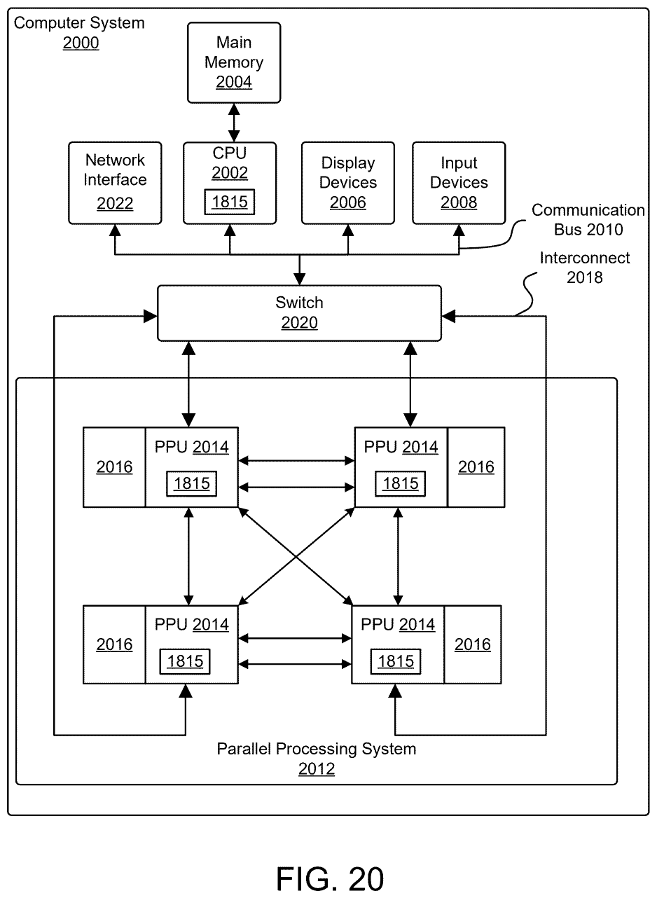

FIG. 20 illustrates a computer system 2000, according to at least one embodiment. In at least one embodiment, computer system 2000 is configured to implement various processes and methods described throughout this disclosure.

In at least one embodiment, computer system 2000 comprises, without limitation, at least one central processing unit (“CPU”) 2002 that is connected to a communication bus 2010 implemented using any suitable protocol, such as PCI (“Peripheral Component Interconnect”), peripheral component interconnect express (“PCI-Express”), AGP (“Accelerated Graphics Port”), HyperTransport, or any other bus or point-to-point communication protocol(s). In at least one embodiment, computer system 2000 includes, without limitation, a main memory 2004 and control logic (e.g., implemented as hardware, software, or a combination thereof) and data are stored in main memory 2004, which may take form of random access memory (“RAM”). In at least one embodiment, a network interface subsystem (“network interface”) 2022 provides an interface to other computing devices and networks for receiving data from and transmitting data to other systems with computer system 2000.

In at least one embodiment, computer system 2000, in at least one embodiment, includes, without limitation, input devices 2008, a parallel processing system 2012, and display devices 2006 that can be implemented using a conventional cathode ray tube (“CRT”), a liquid crystal display (“LCD”), a light emitting diode (“LED”) display, a plasma display, or other suitable display technologies. In at least one embodiment, user input is received from input devices 2008 such as keyboard, mouse, touchpad, microphone, etc. In at least one embodiment, each module described herein can be situated on a single semiconductor platform to form a processing system.

Inference and/or training logic 1815 are used to perform inferencing and/or training operations associated with one or more embodiments. In at least one embodiment, inference and/or training logic 1815 may be used in system FIG. 20 for inferencing or predicting operations based, at least in part, on weight parameters calculated using neural network training operations, neural network functions and/or architectures, or neural network use cases described herein.

Embodiments presented herein can manage various aspects of an operational management system for a computing environment, as may relate to the cleaning, cutover, or adjustment of one or more cooling or power systems.

In at least one embodiment, referring to FIG. 20, computer programs in form of machine-readable executable code or computer control logic algorithms are stored in main memory 2004 and/or secondary storage. Computer programs, if executed by one or more processors, enable computer system 2000 to perform various functions in accordance with at least one embodiment. In at least one embodiment, main memory 2004, storage, and/or any other storage are possible examples of computer-readable media. In at least one embodiment, secondary storage may refer to any suitable storage device or system such as a hard disk drive and/or a removable storage drive, representing a floppy disk drive, a magnetic tape drive, a compact disk drive, digital versatile disk (“DVD”) drive, recording device, universal serial bus (“USB”) flash memory, etc. In at least one embodiment, architecture and/or functionality of various previous FIGS. 1-16 are implemented in context of CPU 2002, parallel processing system 2012, an integrated circuit capable of at least a portion of capabilities of both CPU 2002, parallel processing system 2012, a chipset (e.g., a group of integrated circuits designed to work and sold as a unit for performing related functions, etc.), and/or any suitable combination of integrated circuit(s).

In at least one embodiment, architecture and/or functionality of various previous FIGS. 1-16 are implemented in context of a general computer system, a circuit board system, a game console system dedicated for entertainment purposes, an application-specific system, and more. In at least one embodiment, computer system 2000 may take form of a desktop computer, a laptop computer, a tablet computer, servers, supercomputers, a smart-phone (e.g., a wireless, hand-held device), personal digital assistant (“PDA”), a digital camera, a vehicle, a head mounted display, a hand-held electronic device, a mobile phone device, a television, workstation, game consoles, embedded system, and/or any other type of logic.

In at least one embodiment, parallel processing system 2012 includes, without limitation, a plurality of parallel processing units (“PPUs”) 2014 and associated memories 2016. In at least one embodiment, PPUs 2014 are connected to a host processor or other peripheral devices via an interconnect 2018 and a switch 2020 or multiplexer. In at least one embodiment, parallel processing system 2012 distributes computational tasks across PPUs 2014 which can be parallelizable—for example, as part of distribution of computational tasks across multiple graphics processing unit (“GPU”) thread blocks. In at least one embodiment, memory is shared and accessible (e.g., for read and/or write access) across some or all of PPUs 2014, although such shared memory may incur performance penalties relative to use of local memory and registers resident to a PPU 2014. In at least one embodiment, operation of PPUs 2014 is synchronized through use of a command such as _syncthreads( ), wherein all threads in a block (e.g., executed across multiple PPUs 2014) to reach a certain point of execution of code before proceeding.

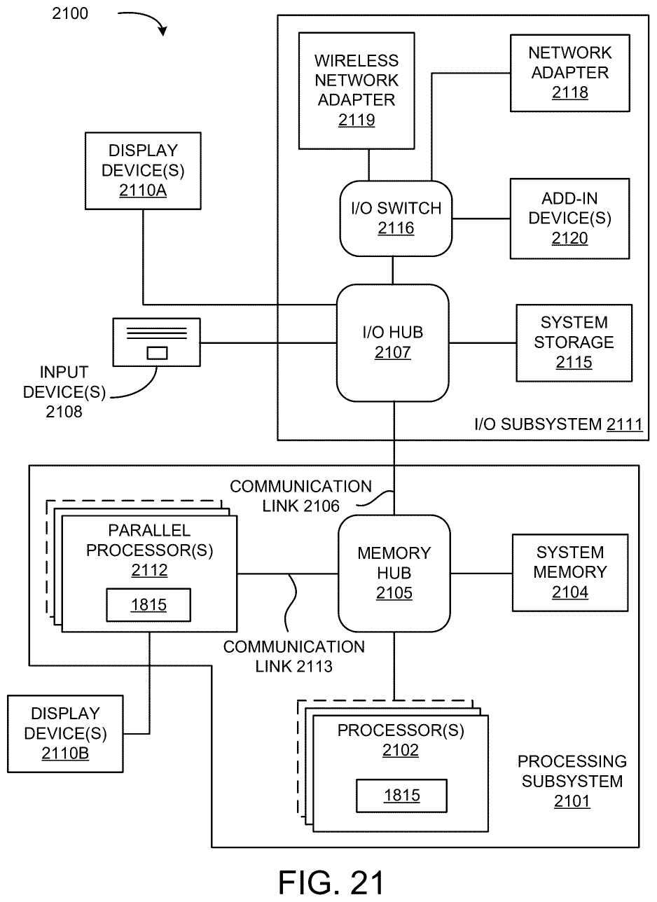

FIG. 21 is a block diagram illustrating a computing system 2100 according to at least one embodiment. In at least one embodiment, computing system 2100 includes a processing subsystem 2101 having one or more processor(s) 2102 and a system memory 2104 communicating via an interconnection path that may include a memory hub 2105. In at least one embodiment, memory hub 2105 may be a separate component within a chipset component or may be integrated within one or more processor(s) 2102. In at least one embodiment, memory hub 2105 couples with an I/O subsystem 2111 via a communication link 2106. In at least one embodiment, I/O subsystem 2111 includes an I/O hub 2107 that can enable computing system 2100 to receive input from one or more input device(s) 2108. In at least one embodiment, I/O hub 2107 can enable a display controller, which may be included in one or more processor(s) 2102, to provide outputs to one or more display device(s) 2110A. In at least one embodiment, one or more display device(s) 2110A coupled with I/O hub 2107 can include a local, internal, or embedded display device.

In at least one embodiment, processing subsystem 2101 includes one or more parallel processor(s) 2112 coupled to memory hub 2105 via a bus or other communication link 2113. In at least one embodiment, communication link 2113 may use one of any number of standards based communication link technologies or protocols, such as but not limited to PCI Express, or may be a vendor-specific communications interface or communications fabric. In at least one embodiment, one or more parallel processor(s) 2112 form a computationally focused parallel or vector processing system that can include a large number of processing cores and/or processing clusters, such as a many-integrated core (MIC) processor. In at least one embodiment, some or all of parallel processor(s) 2112 form a graphics processing subsystem that can output pixels to one of one or more display device(s) 2110A coupled via I/O hub 2107. In at least one embodiment, parallel processor(s) 2112 can also include a display controller and display interface (not shown) to enable a direct connection to one or more display device(s) 2110B. In at least one embodiment, parallel processor(s) 2112 include one or more cores, such as graphics cores 2100 discussed herein.

In at least one embodiment, a system storage unit 2115 can connect to I/O hub 2107 to provide a storage mechanism for computing system 2100. In at least one embodiment, an I/O switch 2116 can be used to provide an interface mechanism to enable connections between I/O hub 2107 and other components, such as a network adapter 2118 and/or a wireless network adapter 2119 that may be integrated into platform, and various other devices that can be added via one or more add-in device(s) 2120. In at least one embodiment, network adapter 2118 can be an Ethernet adapter or another wired network adapter. In at least one embodiment, wireless network adapter 2119 can include one or more of a Wi-Fi, Bluetooth, near field communication (NFC), or other network device that includes one or more wireless radios.

In at least one embodiment, computing system 2100 can include other components not explicitly shown, including USB or other port connections, optical storage drives, video capture devices, and like, may also be connected to I/O hub 2107. In at least one embodiment, communication paths interconnecting various components in FIG. 21 may be implemented using any suitable protocols, such as PCI (Peripheral Component Interconnect) based protocols (e.g., PCI-Express), or other bus or point-to-point communication interfaces and/or protocol(s), such as NV-Link high-speed interconnect, or interconnect protocols.

In at least one embodiment, parallel processor(s) 2112 incorporate circuitry optimized for graphics and video processing, including, for example, video output circuitry, and constitutes a graphics processing unit (GPU), e.g., parallel processor(s) 2112 includes graphics core 2100. In at least one embodiment, parallel processor(s) 2112 incorporate circuitry optimized for general purpose processing. In at least embodiment, components of computing system 2100 may be integrated with one or more other system elements on a single integrated circuit. For example, in at least one embodiment, parallel processor(s) 2112, memory hub 2105, processor(s) 2102, and I/O hub 2107 can be integrated into a system on chip (SoC) integrated circuit. In at least one embodiment, components of computing system 2100 can be integrated into a single package to form a system in package (SIP) configuration. In at least one embodiment, at least a portion of components of computing system 2100 can be integrated into a multi-chip module (MCM), which can be interconnected with other multi-chip modules into a modular computing system.

Inference and/or training logic 1815 are used to perform inferencing and/or training operations associated with one or more embodiments. In at least one embodiment, inference and/or training logic 1815 may be used in system FIG. 21 for inferencing or predicting operations based, at least in part, on weight parameters calculated using neural network training operations, neural network functions and/or architectures, or neural network use cases described herein.

Embodiments presented herein can manage various aspects of an operational management system for a computing environment, as may relate to the cleaning, cutover, or adjustment of one or more cooling or power systems.

### Processors

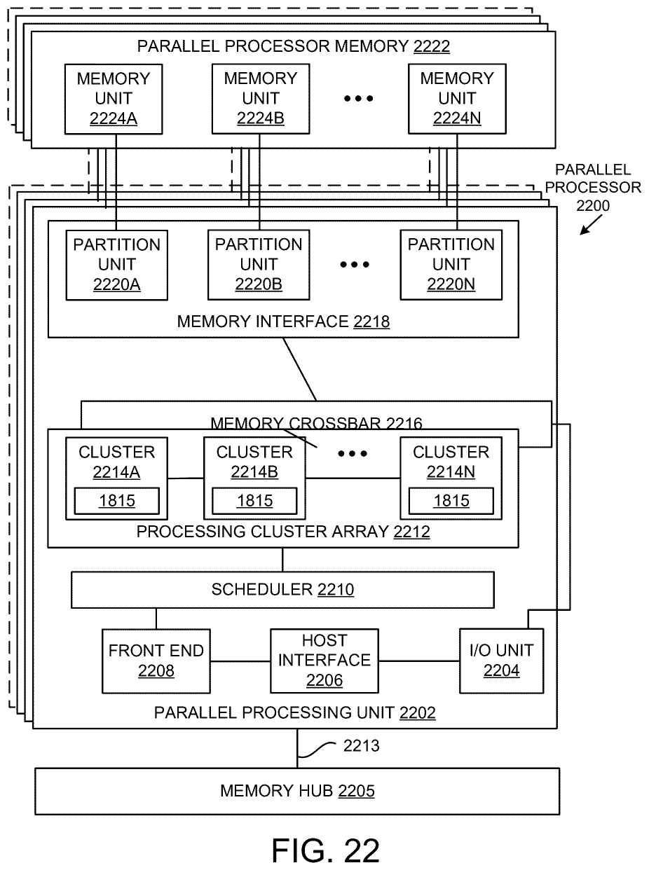

FIG. 22 illustrates a parallel processor 2200 according to at least one embodiment. In at least one embodiment, various components of parallel processor 2200 may be implemented using one or more integrated circuit devices, such as programmable processors, application specific integrated circuits (ASICs), or field programmable gate arrays (FPGA). In at least one embodiment, illustrated parallel processor 2200 is a variant of one or more parallel processor(s) 2112 shown in FIG. 21 according to an exemplary embodiment. In at least one embodiment, a parallel processor 2200 includes one or more graphics cores 2400.

In at least one embodiment, parallel processor 2200 includes a parallel processing unit 2202. In at least one embodiment, parallel processing unit 2202 includes an I/O unit 2204 that enables communication with other devices, including other instances of parallel processing unit 2202. In at least one embodiment, I/O unit 2204 may be directly connected to other devices. In at least one embodiment, I/O unit 2204 connects with other devices via use of a hub or switch interface, such as a memory hub 2205. In at least one embodiment, connections between memory hub 2205 and I/O unit 2204 form a communication link 2213. In at least one embodiment, I/O unit 2204 connects with a host interface 2206 and a memory crossbar 2216, where host interface 2206 receives commands directed to performing processing operations and memory crossbar 2216 receives commands directed to performing memory operations.

In at least one embodiment, when host interface 2206 receives a command buffer via I/O unit 2204, host interface 2206 can direct work operations to perform those commands to a front end 2208. In at least one embodiment, front end 2208 couples with a scheduler 2210 (which may be referred to as a sequencer), which is configured to distribute commands or other work items to a processing cluster array 2212. In at least one embodiment, scheduler 2210 ensures that processing cluster array 2212 is properly configured and in a valid state before tasks are distributed to a cluster of processing cluster array 2212. In at least one embodiment, scheduler 2210 is implemented via firmware logic executing on a microcontroller. In at least one embodiment, microcontroller implemented scheduler 2210 is configurable to perform complex scheduling and work distribution operations at coarse and fine granularity, enabling rapid preemption and context switching of threads executing on processing array 2212. In at least one embodiment, host software can prove workloads for scheduling on processing cluster array 2212 via one of multiple graphics processing paths. In at least one embodiment, workloads can then be automatically distributed across processing array cluster 2212 by scheduler 2210 logic within a microcontroller including scheduler 2210.

In at least one embodiment, processing cluster array 2212 can include up to “N” processing clusters (e.g., cluster 2214A, cluster 2214B, through cluster 2214N), where “N” represents a positive integer (which may be a different integer “N” than used in other figures). In at least one embodiment, each cluster 2214A-2214N of processing cluster array 2212 can execute a large number of concurrent threads. In at least one embodiment, scheduler 2210 can allocate work to clusters 2214A-2214N of processing cluster array 2212 using various scheduling and/or work distribution algorithms, which may vary depending on workload arising for each type of program or computation. In at least one embodiment, scheduling can be handled dynamically by scheduler 2210, or can be assisted in part by compiler logic during compilation of program logic configured for execution by processing cluster array 2212. In at least one embodiment, different clusters 2214A-2214N of processing cluster array 2212 can be allocated for processing different types of programs or for performing different types of computations.

In at least one embodiment, processing cluster array 2212 can be configured to perform various types of parallel processing operations. In at least one embodiment, processing cluster array 2212 is configured to perform general-purpose parallel compute operations. For example, in at least one embodiment, processing cluster array 2212 can include logic to execute processing tasks including filtering of video and/or audio data, performing modeling operations, including physics operations, and performing data transformations.

In at least one embodiment, processing cluster array 2212 is configured to perform parallel graphics processing operations. In at least one embodiment, processing cluster array 2212 can include additional logic to support execution of such graphics processing operations, including but not limited to, texture sampling logic to perform texture operations, as well as tessellation logic and other vertex processing logic. In at least one embodiment, processing cluster array 2212 can be configured to execute graphics processing related shader programs such as but not limited to, vertex shaders, tessellation shaders, geometry shaders, and pixel shaders. In at least one embodiment, parallel processing unit 2202 can transfer data from system memory via I/O unit 2204 for processing. In at least one embodiment, during processing, transferred data can be stored to on-chip memory (e.g., parallel processor memory 2222) during processing, then written back to system memory.

In at least one embodiment, when parallel processing unit 2202 is used to perform graphics processing, scheduler 2210 can be configured to divide a processing workload into approximately equal sized tasks, to better enable distribution of graphics processing operations to multiple clusters 2214A-2214N of processing cluster array 2212. In at least one embodiment, portions of processing cluster array 2212 can be configured to perform different types of processing. For example, in at least one embodiment, a first portion may be configured to perform vertex shading and topology generation, a second portion may be configured to perform tessellation and geometry shading, and a third portion may be configured to perform pixel shading or other screen space operations, to produce a rendered image for display. In at least one embodiment, intermediate data produced by one or more of clusters 2214A-2214N may be stored in buffers to allow intermediate data to be transmitted between clusters 2214A-2214N for further processing.

In at least one embodiment, processing cluster array 2212 can receive processing tasks to be executed via scheduler 2210, which receives commands defining processing tasks from front end 2208. In at least one embodiment, processing tasks can include indices of data to be processed, e.g., surface (patch) data, primitive data, vertex data, and/or pixel data, as well as state parameters and commands defining how data is to be processed (e.g., what program is to be executed). In at least one embodiment, scheduler 2210 may be configured to fetch indices corresponding to tasks or may receive indices from front end 2208. In at least one embodiment, front end 2208 can be configured to ensure processing cluster array 2212 is configured to a valid state before a workload specified by incoming command buffers (e.g., batch-buffers, push buffers, etc.) is initiated.

In at least one embodiment, each of one or more instances of parallel processing unit 2202 can couple with a parallel processor memory 2222. In at least one embodiment, parallel processor memory 2222 can be accessed via memory crossbar 2216, which can receive memory requests from processing cluster array 2212 as well as I/O unit 2204. In at least one embodiment, memory crossbar 2216 can access parallel processor memory 2222 via a memory interface 2218. In at least one embodiment, memory interface 2218 can include multiple partition units (e.g., partition unit 2220A, partition unit 2220B, through partition unit 2220N) that can each couple to a portion (e.g., memory unit) of parallel processor memory 2222. In at least one embodiment, a number of partition units 2220A-2220N is configured to be equal to a number of memory units, such that a first partition unit 2220A has a corresponding first memory unit 2224A, a second partition unit 2220B has a corresponding memory unit 2224B, and an N-th partition unit 2220N has a corresponding N-th memory unit 2224N. In at least one embodiment, a number of partition units 2220A-2220N may not be equal to a number of memory units.

In at least one embodiment, memory units 2224A-2224N can include various types of memory devices, including dynamic random access memory (DRAM) or graphics random access memory, such as synchronous graphics random access memory (SGRAM), including graphics double data rate (GDDR) memory. In at least one embodiment, memory units 2224A-2224N may also include 3D stacked memory, including but not limited to high bandwidth memory (HBM), HBM2e, or HDM3. In at least one embodiment, render targets, such as frame buffers or texture maps may be stored across memory units 2224A-2224N, allowing partition units 2220A-2220N to write portions of each render target in parallel to efficiently use available bandwidth of parallel processor memory 2222. In at least one embodiment, a local instance of parallel processor memory 2222 may be excluded in favor of a unified memory design that uses system memory in conjunction with local cache memory.

In at least one embodiment, any one of clusters 2214A-2214N of processing cluster array 2212 can process data that will be written to any of memory units 2224A-2224N within parallel processor memory 2222. In at least one embodiment, memory crossbar 2216 can be configured to transfer an output of each cluster 2214A-2214N to any partition unit 2220A-2220N or to another cluster 2214A-2214N, which can perform additional processing operations on an output. In at least one embodiment, each cluster 2214A-2214N can communicate with memory interface 2218 through memory crossbar 2216 to read from or write to various external memory devices. In at least one embodiment, memory crossbar 2216 has a connection to memory interface 2218 to communicate with I/O unit 2204, as well as a connection to a local instance of parallel processor memory 2222, enabling processing units within different processing clusters 2214A-2214N to communicate with system memory or other memory that is not local to parallel processing unit 2202. In at least one embodiment, memory crossbar 2216 can use virtual channels to separate traffic streams between clusters 2214A-2214N and partition units 2220A-2220N.

In at least one embodiment, multiple instances of parallel processing unit 2202 can be provided on a single add-in card, or multiple add-in cards can be interconnected. In at least one embodiment, different instances of parallel processing unit 2202 can be configured to interoperate even if different instances have different numbers of processing cores, different amounts of local parallel processor memory, and/or other configuration differences. For example, in at least one embodiment, some instances of parallel processing unit 2202 can include higher precision floating point units relative to other instances. In at least one embodiment, systems incorporating one or more instances of parallel processing unit 2202 or parallel processor 2200 can be implemented in a variety of configurations and form factors, including but not limited to desktop, laptop, or handheld personal computers, servers, workstations, game consoles, and/or embedded systems.

Inference and/or training logic 1815 are used to perform inferencing and/or training operations associated with one or more embodiments. In at least one embodiment, inference and/or training logic 1815 may be used in system FIG. 22 for inferencing or predicting operations based, at least in part, on weight parameters calculated using neural network training operations, neural network functions and/or architectures, or neural network use cases described herein.

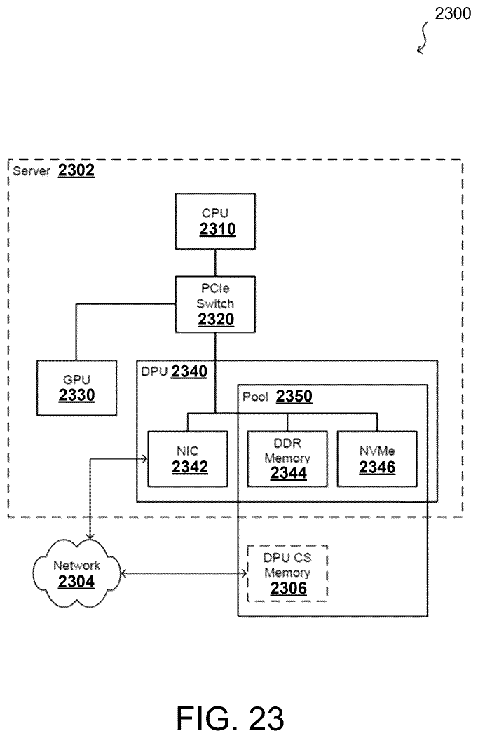

FIG. 23 illustrates an example computing environment 2300 in which forward pass offloading to available memory can be performed, in accordance with at least one embodiment. It should be appreciated that embodiments of the present disclosure may also be used with reference to alternative environments and that specific discussion of components may be provided by way of non-limiting example and may include equivalents. Moreover, various features have been removed for clarity and conciseness. Additionally, systems and methods may be used with a variety of different architectures. The example computing environment 2300 may include a server 2302 which may be used to perform HPC workloads, such as AI training or machine learning model training. In an embodiment, the server 2302 may be an application instance or a compute node. The server 2302 may include a CPU 2310 associated with a switch 2320, such as a peripheral component interconnect express (PCIe) switch, which may control at least some data transmission over communication paths interconnecting various components. In an embodiment, the CPU 2310 may include a root complex processor.

The PCIe switch 2320 may also be associated with a GPU 2330 and a DPU 2340, and may transmit data between at least some of the CPU 2310, the GPU 2330, the DPU 2340, and other components. In an embodiment, the PCIe switch 2320 may be associated with more than one GPU or more than one DPU. In another embodiment, the PCIe switch 2320 may be located within the DPU 2340. The PCIe switch 2320 may manage the transfer of at least some data between the CPU 2310, the GPU 2330, and the DPU 2340. In another embodiment, the number of GPUs associated with the PCIe switch 2320 may be equal to the number of DPUs associated with the PCIe switch 2320. In at least one embodiment, the server 2302 may include, without limitation, any number of the CPUs 2310, the PCIe switches 2320, the GPUs 2330, and/or the DPUs 2340, in any combination. For example, in at least one embodiment, server 2302 could include eight, sixteen, thirty-two, and/or more GPUs 2330. In at least one embodiment, communication paths interconnecting various components, including but not limited to the CPU 2310, the PCIe switch 2320, the GPU 2330, and the DPU 2340, in FIG. 23 may be implemented using any suitable protocols, such as peripheral component interconnect (PCI) based protocols (e.g., PCIe), or other bus or point-to-point communication interfaces and/or protocol(s), such as NV-Link high-speed interconnect, or interconnect protocols.

The DPU 2340 may include a network interface card (NIC) 2342, a DDR memory 2344, and a non-volatile memory express (NVMe) device 2346. The NIC 2342 may be able to interface with a network 2304, which may also interface with additional NVMe devices available to the DPU 2340, such as over fabric. In an embodiment, the DPU 2340 may not include the NVMe device 2346. In another embodiment, the NVMe device 2346 may be located on the server 2302 and not on the DPU 2340. In yet another embodiment, the computing environment 2300 may include more than one of the NVMe device 2346, such as a first NVMe device in the DPU 2340 and a second first NVMe device on the server 2302 an associated directly with the PCIe switch 2320. In an embodiment, the DPU 2340 may not include the DDR memory 2344 and may include a computational storage services (CSS) in place of, or in addition to, the DDR memory 2344. For example, computing environment 2300 may include DPU computational storage (CS) memory 2306 available to the DPU 2340 as part of the CSS. The network 2304 may be able to interface with the DPU CS memory 2306 through the NIC 2342, according to any suitable interface protocol, such as remote direct memory access (RDMA) over Ethernet, InfiniBand, Fiber Channel, etc.

The total memory of the computing environment 2300 available for data storage may be expanded through the use of the DPU 2340 on nodes of the system. The DPU 2340 may have access to a pool 2350 of memory already available to the server 2302, such as double data rate (DDR) memory, on-board NVMe devices, NVMe devices over fabric, and CS. The pool 2350 of memory may include at least one of the DDR memory 2344, NVMe 2346, and the DPU CS memory 2306. The DPU 2340 may also be able to access the available memory of other DPUs as part of the pool 2350, and other DPUs may be able to access the available memory of DPU 2340, such as the pool 2350. This available memory can be accessed and utilized for data storage, without the addition of compute resources, such as compute nodes, which would be required using other solutions. The available pool 2350 accessible to the DPU 2340 may be provisioned for the server 2302 to expand the total memory available for data storage, such as to reduce the data storage load on the CPU 2310 or the GPU 2330, which can instead increase the utilization of their memory for processing. For example, during training of an AI, the model states, residual states, activation functions, and checkpoints can be stored, or offloaded, on the pool 2350 accessible to the DPU 2340.

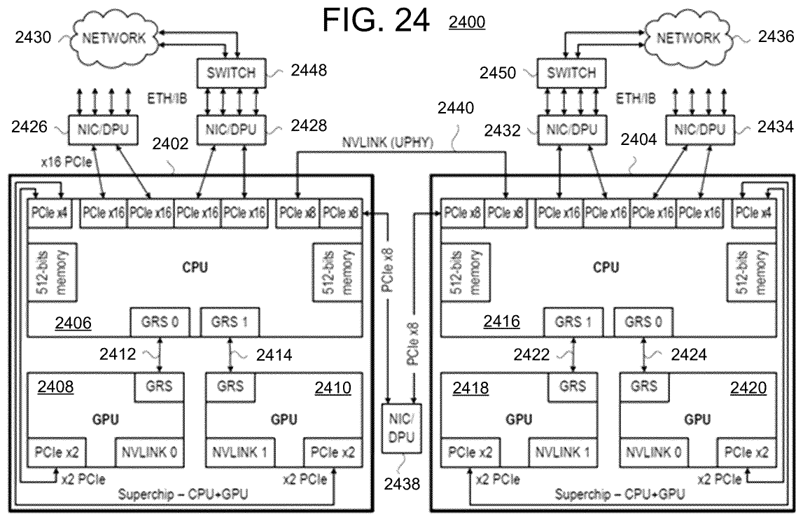

FIG. 24 is a block diagram that schematically illustrates a computing system 2400, e.g., a data center or a High-Performance Computing (HPC) cluster, in accordance with an embodiment that is described herein. System 2400 comprises a plurality of subsystems, e.g., multiple processing devices coupled to each other, multiple network devices, and multiple networks, according to at least one embodiment. Computing system 2400 is designed with multiple integrated circuits (referred to as processing devices), where each integrated circuit can include one or more CPUs and GPUs, forming a powerful and flexible architecture.

The various processing devices are interconnected via an NVLink or other high-speed interconnect, enabling high-speed communication between the subsystems, and are also connected through a NIC or DPU to ensure efficient data transfer across computing system 2400 and to one or more external networks 2430, 2436. In the present example, system 2400 comprises a packet switch 2448 that connects NIC/DPU 2428 to network 2430, and a packet switch 2450 that connects NIC/DPU 2432 to network 2436.

The coupling of processing devices through NVLink allows for seamless data exchange and parallel processing, enhancing overall computational performance. The processing devices are connected to multiple networks through one or more network interface cards (NICs) or DPUs, enabling the system to handle complex, multi-network tasks with high bandwidth and low latency. This configuration is highly suitable for demanding applications that require significant processing power, such as artificial intelligence (AI), machine learning (ML), and data-intensive computing, while ensuring robust connectivity and scalability across various networked environments. The integrated circuits of the computing system 2400 can include one or more CPUs and one or more GPUs.

FIG. 24 also demonstrates an example architecture of a multi-GPU architecture. As illustrated in the figure, computing system 2400 includes a processing device 2402 with a multi-GPU architecture. In particular, processing device 2402 may be a system on chip and includes multiple subsystems such as a CPU 2406, a GPU 2408, and a GPU 2410. CPU 2406 can be coupled to GPU 2408 via a die-to-die (D2D) or chip-to-chip (C2C) interconnect 2412, such as a Ground-Referenced Signaling interconnect (GRS interconnect). CPU 2406 can be coupled to GPU 2410 via a D2D or C2C interconnect 2414. CPU 2406 can also couple to GPU 2408 and GPU 2410 via PCIe interconnects.

CPU 2406 can be coupled to one or more NICs or DPUs, which are coupled to one or more networks. For example, as illustrated in FIG. 24, CPU 2406 is coupled to a first NIC/DPU 2426, which is coupled to a network 2430. CPU 2406 is also coupled to a second NIC/DPU 2428, which is coupled to network 2430 via switch 2448. NIC/DPU 2426 and NIC/DPU 2428 can be coupled to network 2430 over Ethernet (ETH), NVLINK or InfiniBand (IB) connections, for example.

Computing system 2400 also includes a processing device 2404 with a multi-GPU architecture. In particular, processing device 2404 includes multiple subsystems including a CPU 2416, a GPU 2418, and a GPU 2420. CPU 2416 can be coupled to GPU 2418 via an D2D or C2C interconnect 2422. CPU 2416 can be coupled to GPU 2420 via a D2D or C2C interconnect 2424. CPU 2416 can also couple to GPU 2418 and GPU 2420 via PCIe interconnects. CPU 2416 can be coupled to one or more NICs or DPUs, which are coupled to one or more networks. For example, as illustrated in FIG. 24, CPU 2416 is coupled to a first NIC/DPU 2432, which is coupled to a network 2436. CPU 2416 is also coupled to a second NIC/DPU 2434, which is coupled to network 2436 via switch 2450. NIC/DPU 2432 and NIC/DPU 2434 can be coupled to network 2436 over Ethernet (ETH), NVLINK or InfiniBand (IB) connections.

In at least one embodiment, processing device 2402 and processing device 2404 can communication with each other via a NIC/DPU 2438, such as over PCIe interconnects. Processing device 2402 and processing device 2404 can also communicate with each other over a high-bandwidth communication interconnects 2440, such as an NVLink interconnect or other high-speed interconnects. The packet switches in FIG. 24 may comprise, for example, Nvidia Quantum-2 switches. The NICs/DPUs in the figure may comprise, for example, Nvidia Bluefield DPUs.

In various embodiments, any of the network devices of system 2400, e.g., any of NICs/DPUs 2426, 2428, 2432, 2434 and 2438, and/or any of switches 2448 and 2450, may use ILI packets in accordance with the techniques described herein.

Embodiments presented herein can manage various aspects of an operational management system for a computing environment, as may relate to the cleaning, cutover, or adjustment of one or more cooling or power systems.

Various embodiments can be described by the following clauses:
1. A system, comprising:
one or more tag readers in a computing environment to determine, from markers associated with one or more heat-generating components positioned proximate one of the tag readers, one or more operational requirements for the heat-generating components in the computing environment; and
a cooling manager to receive the one or more operational requirements for the heat-generating components and determine one or more adjustments to be performed with respect to a at least one source of cooling liquid based, at least in part, on the one or more operational requirements.
2. The system of clause 1, wherein the one or more tag readers are further configured to determine one or more additional operational requirements for one or more additional heat-generating components subsequently installed proximate the one or more tag readers, and wherein the cooling manager is further to determine whether to make one or more additional adjustments based in part upon the one or more additional operational requirements.
3. The system of clause 1, wherein the heat-generating components include at least one server, switch, router, network interface controller, tray, system on chip, or compute resource.
4. The system of clause 1, wherein the tag readers attached to the heat-generating components include at least radio frequency identification (RFID) tags, near-field communications (NFC) tags, QR codes, bar codes, identification stickers, physical connections to memory, or Bluetooth transmitters.
5. The system of clause 1, further comprising:
at least one source of air cooling, wherein the cooling manager is further to determine one or more adjustments to be made with respect to the at least one source of air cooling based, at least in part, on the one or more operational requirements.
6. The system of clause 1, wherein the one or more tag readers include at least one tag reader positioned on a server rack to detect a tag associated with a server placed in a server tray of the server rack.
7. The system of clause 1, wherein the cooling manager is further able to generate a warning based at least in part upon a current value or a predicted value of the computing environment with respect to the one or more operational requirements.
8. The system of clause 1, wherein the one or more tag readers are further configured to read one or more power requirements or operating temperature limits from the tags associated with the heat-generating components, to be used in determining whether to perform one or more additional adjustments to operation of the computing environment.
9. At least one processor, comprising:
one or more logical units to receive one or more operational requirements read from tags attached to each of a set of electronic components, the one or more operational requirements read by one or more tag readers in response to detecting a change in presence of one or more of the tags, and further to determine whether one or more adjustments are to be automatically performed in order to satisfy a change in the one or more operational requirements.
10. The at least one processor of clause 9, wherein the one or more tag readers are further to determine one or more additional cooling requirements for one or more additional electronic components subsequently installed proximate the one or more tag readers, and wherein an operations manager is further to determine whether to make one or more additional adjustments based in part upon the one or more additional cooling requirements.
11. The at least one processor of clause 9, wherein the set of electronic components include at least one server, switch, router, network interface controller, tray, system on chip, or compute resource.
12. The at least one processor of clause 9, wherein the tags attached to the electronic components include at least radio frequency identification (RFID) tags, near-field communications (NFC) tags, QR codes, bar codes, identification stickers, physical connections to memory, or Bluetooth transmitters.
13. The at least one processor of clause 9, wherein the one or more logical units are further configured to:
determine one or more adjustments to be made with respect to at least one source of air cooling based, in part, on one or more cooling requirements.
14. The at least one processor of clause 9, wherein the one or more tag readers include at least one tag reader positioned on a server rack to detect a tag associated with a server placed in a server tray of the server rack.
15. The at least one processor of clause 9, wherein the one or more logical units are further configured to:
generate one or more alerts in response to a current value or a predicted value of a computing environment falling outside one or more cooling requirements and an automatic adjustment unable to be performed to cause the current value or the predicted value to fall inside the one or more cooling requirements.
16. A computer-implemented method comprising:
detecting, using a tag reader, a tag associated with a heat-generating component installed in a data center;
determining, from information associated with the tag, one or more cooling requirements of the heat-generating component; and
performing, automatically and based at least in part upon aggregating the one or more cooling requirements with a set of additional cooling requirements for a plurality of other heat-generating components installed in the data center, one or more adjustments to a cooling system of the data center.
17. The computer-implemented method of clause 16, further comprising:
determining, using at least one additional tag reader, one or more additional cooling requirements for one or more additional electronic components subsequently installed proximate the at least one additional tag reader; and
causing an operations manager to determine whether to automatically perform one or more additional adjustments based in part upon the one or more additional cooling requirements.
18. The computer-implemented method of clause 16, wherein the plurality of heat-generating components includes at least one server, switch, router, network interface controller, tray, system on chip, or compute resource.
19. The computer-implemented method of clause 16, wherein the tags attached to the heat-generating components include at least radio frequency identification (RFID) tags, near-field communications (NFC) tags, QR codes, bar codes, identification stickers, physical connections to memory, or Bluetooth transmitters.
20. The computer-implemented method of clause 16, further comprising:
determining, based in part on one or more additional requirements of the heat-generating component, one or more additional adjustments to be made with respect to at least one source of air cooling or power.
21. The computer-implemented method of clause 16, further comprising:
determining, from information associated with the tag, at least one of expected flow rate, required cooling capacity, expected pressure, minimum or maximum temperature of the heat-generating component, liquid viscosity requirements, cooling loop configuration, maintenance schedule or alerts, cooling efficiency metrics, pressure drops, heat generation profile, and emergency shutdown procedures.

Other variations are within spirit of present disclosure. Thus, while disclosed techniques are susceptible to various modifications and alternative constructions, certain illustrated embodiments thereof are shown in drawings and have been described above in detail. It should be understood, however, that there is no intention to limit disclosure to specific form or forms disclosed, but on contrary, intention is to cover all modifications, alternative constructions, and equivalents falling within spirit and scope of disclosure, as defined in appended claims.

Use of terms “a” and “an” and “the” and similar referents in context of describing disclosed embodiments (especially in context of following claims) are to be construed to cover both singular and plural, unless otherwise indicated herein or clearly contradicted by context, and not as a definition of a term. Terms “comprising,” “having,” “including,” and “containing” are to be construed as open-ended terms (meaning “including, but not limited to,”) unless otherwise noted. “Connected,” when unmodified and referring to physical connections, is to be construed as partly or wholly contained within, attached to, or joined together, even if there is something intervening. Recitation of ranges of values herein are merely intended to serve as a shorthand method of referring individually to each separate value falling within range, unless otherwise indicated herein and each separate value is incorporated into specification as if it were individually recited herein. In at least one embodiment, use of term “set” (e.g., “a set of items”) or “subset” unless otherwise noted or contradicted by context, is to be construed as a nonempty collection comprising one or more members. Further, unless otherwise noted or contradicted by context, term “subset” of a corresponding set does not necessarily denote a proper subset of corresponding set, but subset and corresponding set may be equal.

Conjunctive language, such as phrases of form “at least one of A, B, and C,” or “at least one of A, B and C,” unless specifically stated otherwise or otherwise clearly contradicted by context, is otherwise understood with context as used in general to present that an item, term, etc., may be either A or B or C, or any nonempty subset of set of A and B and C. For instance, in illustrative example of a set having three members, conjunctive phrases “at least one of A, B, and C” and “at least one of A, B and C” refer to any of following sets: {A}, {B}, {C}, {A, B}, {A, C}, {B, C}, {A, B, C}. Thus, such conjunctive language is not generally intended to imply that certain embodiments require at least one of A, at least one of B and at least one of C each to be present. In addition, unless otherwise noted or contradicted by context, term “plurality” indicates a state of being plural (e.g., “a plurality of items” indicates multiple items). In at least one embodiment, number of items in a plurality is at least two, but can be more when so indicated either explicitly or by context. Further, unless stated otherwise or otherwise clear from context, phrase “based on” means “based at least in part on” and not “based solely on.”

Operations of processes described herein can be performed in any suitable order unless otherwise indicated herein or otherwise clearly contradicted by context. In at least one embodiment, a process such as those processes described herein (or variations and/or combinations thereof) is performed under control of one or more computer systems configured with executable instructions and is implemented as code (e.g., executable instructions, one or more computer programs or one or more applications) executing collectively on one or more processors, by hardware or combinations thereof. In at least one embodiment, code is stored on a computer-readable storage medium, for example, in form of a computer program comprising a plurality of instructions executable by one or more processors. In at least one embodiment, a computer-readable storage medium is a non-transitory computer-readable storage medium that excludes transitory signals (e.g., a propagating transient electric or electromagnetic transmission) but includes non-transitory data storage circuitry (e.g., buffers, cache, and queues) within transceivers of transitory signals. In at least one embodiment, code (e.g., executable code or source code) is stored on a set of one or more non-transitory computer-readable storage media having stored thereon executable instructions (or other memory to store executable instructions) that, when executed (i.e., as a result of being executed) by one or more processors of a computer system, cause computer system to perform operations described herein. In at least one embodiment, set of non-transitory computer-readable storage media comprises multiple non-transitory computer-readable storage media and one or more of individual non-transitory storage media of multiple non-transitory computer-readable storage media lack all of code while multiple non-transitory computer-readable storage media collectively store all of code. In at least one embodiment, executable instructions are executed such that different instructions are executed by different processors—for example, a non-transitory computer-readable storage medium store instructions and a main central processing unit (“CPU”) executes some of instructions while a graphics processing unit (“GPU”) executes other instructions. In at least one embodiment, different components of a computer system have separate processors and different processors execute different subsets of instructions.

In at least one embodiment, an arithmetic logic unit is a set of combinational logic circuitry that takes one or more inputs to produce a result. In at least one embodiment, an arithmetic logic unit is used by a processor to implement mathematical operation such as addition, subtraction, or multiplication. In at least one embodiment, an arithmetic logic unit is used to implement logical operations such as logical AND/OR or XOR. In at least one embodiment, an arithmetic logic unit is stateless, and made from physical switching components such as semiconductor transistors arranged to form logical gates. In at least one embodiment, an arithmetic logic unit may operate internally as a stateful logic circuit with an associated clock. In at least one embodiment, an arithmetic logic unit may be constructed as an asynchronous logic circuit with an internal state not maintained in an associated register set. In at least one embodiment, an arithmetic logic unit is used by a processor to combine operands stored in one or more registers of the processor and produce an output that can be stored by the processor in another register or a memory location.

In at least one embodiment, as a result of processing an instruction retrieved by the processor, the processor presents one or more inputs or operands to an arithmetic logic unit, causing the arithmetic logic unit to produce a result based at least in part on an instruction code provided to inputs of the arithmetic logic unit. In at least one embodiment, the instruction codes provided by the processor to the ALU are based at least in part on the instruction executed by the processor. In at least one embodiment combinational logic in the ALU processes the inputs and produces an output which is placed on a bus within the processor. In at least one embodiment, the processor selects a destination register, memory location, output device, or output storage location on the output bus so that clocking the processor causes the results produced by the ALU to be sent to the desired location.

In the scope of this application, the term arithmetic logic unit, or ALU, is used to refer to any computational logic circuit that processes operands to produce a result. For example, in the present document, the term ALU can refer to a floating point unit, a DSP, a tensor core, a shader core, a coprocessor, or a CPU.

Accordingly, in at least one embodiment, computer systems are configured to implement one or more services that singly or collectively perform operations of processes described herein and such computer systems are configured with applicable hardware and/or software that enable performance of operations. Further, a computer system that implements at least one embodiment of present disclosure is a single device and, in another embodiment, is a distributed computer system comprising multiple devices that operate differently such that distributed computer system performs operations described herein and such that a single device does not perform all operations.

Use of any and all examples, or exemplary language (e.g., “such as”) provided herein, is intended merely to better illuminate embodiments of disclosure and does not pose a limitation on scope of disclosure unless otherwise claimed. No language in specification should be construed as indicating any non-claimed element as essential to practice of disclosure.

In description and claims, terms “coupled” and “connected,” along with their derivatives, may be used. It should be understood that these terms may be not intended as synonyms for each other. Rather, in particular examples, “connected” or “coupled” may be used to indicate that two or more elements are in direct or indirect physical or electrical contact with each other. “Coupled” may also mean that two or more elements are not in direct contact with each other, but yet still co-operate or interact with each other.

Unless specifically stated otherwise, it may be appreciated that throughout specification terms such as “processing,” “computing,” “calculating,” “determining,” or like, refer to action and/or processes of a computer or computing system, or similar electronic computing device, that manipulate and/or transform data represented as physical, such as electronic, quantities within computing system's registers and/or memories into other data similarly represented as physical quantities within computing system's memories, registers or other such information storage, transmission or display devices.

In a similar manner, term “processor” may refer to any device or portion of a device that processes electronic data from registers and/or memory and transform that electronic data into other electronic data that may be stored in registers and/or memory. As non-limiting examples, “processor” may be a CPU or a GPU, DPU, QPU, a plurality of parallel processing units (PPUs). A “computing platform” may comprise one or more processors. As used herein, “software” processes may include, for example, software and/or hardware entities that perform work over time, such as tasks, threads, and intelligent agents. Also, each process may refer to multiple processes, for carrying out instructions in sequence or in parallel, continuously or intermittently. In at least one embodiment, terms “system” and “method” are used herein interchangeably insofar as system may embody one or more methods and methods may be considered a system.

In present document, references may be made to obtaining, acquiring, receiving, or inputting analog or digital data into a subsystem, computer system, or computer-implemented machine. In at least one embodiment, process of obtaining, acquiring, receiving, or inputting analog and digital data can be accomplished in a variety of ways such as by receiving data as a parameter of a function call or a call to an application programming interface. In at least one embodiment, processes of obtaining, acquiring, receiving, or inputting analog or digital data can be accomplished by transferring data via a serial or parallel interface. In at least one embodiment, processes of obtaining, acquiring, receiving, or inputting analog or digital data can be accomplished by transferring data via a computer network from providing entity to acquiring entity. In at least one embodiment, references may also be made to providing, outputting, transmitting, sending, or presenting analog or digital data. In various examples, processes of providing, outputting, transmitting, sending, or presenting analog or digital data can be accomplished by transferring data as an input or output parameter of a function call, a parameter of an application programming interface or interprocess communication mechanism.

Although descriptions herein set forth example implementations of described techniques, other architectures may be used to implement described functionality, and are intended to be within scope of this disclosure. Furthermore, although specific distributions of responsibilities may be defined above for purposes of description, various functions and responsibilities might be distributed and divided in different ways, depending on circumstances.

Furthermore, although subject matter has been described in language specific to structural features and/or methodological acts, it is to be understood that subject matter claimed in appended claims is not necessarily limited to specific features or acts described. Rather, specific features and acts are disclosed as exemplary forms of implementing the claims.

What is claimed is:

1. A system, comprising:
one or more tag readers in a computing environment to determine, from markers associated with one or more heat-generating components positioned proximate one of the tag readers, one or more operational requirements for the heat-generating components in the computing environment; and
a cooling manager to receive the one or more operational requirements for the heat-generating components and determine one or more adjustments to be performed with respect to a at least one source of cooling liquid based, at least in part, on the one or more operational requirements.

2. The system of claim 1, wherein the one or more tag readers are further configured to determine one or more additional operational requirements for one or more additional heat-generating components subsequently installed proximate the one or more tag readers, and wherein the cooling manager is further to determine whether to make one or more additional adjustments based in part upon the one or more additional operational requirements.

3. The system of claim 1, wherein the heat-generating components include at least one server, switch, router, network interface controller, tray, system on chip, or compute resource.

4. The system of claim 1, wherein the tag readers attached to the heat-generating components include at least radio frequency identification (RFID) tags, near-field communications (NFC) tags, QR codes, bar codes, identification stickers, physical connections to memory, or Bluetooth transmitters.

5. The system of claim 1, further comprising:
at least one source of air cooling, wherein the cooling manager is further to determine one or more adjustments to be made with respect to the at least one source of air cooling based, at least in part, on the one or more operational requirements.

6. The system of claim 1, wherein the one or more tag readers include at least one tag reader positioned on a server rack to detect a tag associated with a server placed in a server tray of the server rack.

7. The system of claim 1, wherein the cooling manager is further able to generate a warning based at least in part upon a current value or a predicted value of the computing environment with respect to the one or more operational requirements.

8. The system of claim 1, wherein the one or more tag readers are further configured to read one or more power requirements or operating temperature limits from the tags associated with the heat-generating components, to be used in determining whether to perform one or more additional adjustments to operation of the computing environment.

9. At least one processor, comprising:
one or more logical units to receive one or more operational requirements read from tags attached to each of a set of electronic components, the one or more operational requirements read by one or more tag readers in response to detecting a change in presence of one or more of the tags, and further to determine whether one or more adjustments are to be automatically performed in order to satisfy a change in the one or more operational requirements.

10. The at least one processor of claim 9, wherein the one or more tag readers are further to determine one or more additional cooling requirements for one or more additional electronic components subsequently installed proximate the one or more tag readers, and wherein an operations manager is further to determine whether to make one or more additional adjustments based in part upon the one or more additional cooling requirements.

11. The at least one processor of claim 9, wherein the set of electronic components include at least one server, switch, router, network interface controller, tray, system on chip, or compute resource.

12. The at least one processor of claim 9, wherein the tags attached to the electronic components include at least radio frequency identification (RFID) tags, near-field communications (NFC) tags, QR codes, bar codes, identification stickers, physical connections to memory, or Bluetooth transmitters.

13. The at least one processor of claim 9, wherein the one or more logical units are further configured to:
determine one or more adjustments to be made with respect to at least one source of air cooling based, in part, on one or more cooling requirements.

14. The at least one processor of claim 9, wherein the one or more tag readers include at least one tag reader positioned on a server rack to detect a tag associated with a server placed in a server tray of the server rack.

15. The at least one processor of claim 9, wherein the one or more logical units are further configured to:
generate one or more alerts in response to a current value or a predicted value of a computing environment falling outside one or more cooling requirements and an automatic adjustment unable to be performed to cause the current value or the predicted value to fall inside the one or more cooling requirements.

16. A computer-implemented method comprising:
detecting, using a tag reader, a tag associated with a heat-generating component installed in a data center;
determining, from information associated with the tag, one or more cooling requirements of the heat-generating component; and
performing, automatically and based at least in part upon aggregating the one or more cooling requirements with a set of additional cooling requirements for a plurality of other heat-generating components installed in the data center, one or more adjustments to a cooling system of the data center.

17. The computer-implemented method of claim 16, further comprising:
determining, using at least one additional tag reader, one or more additional cooling requirements for one or more additional electronic components subsequently installed proximate the at least one additional tag reader; and
causing an operations manager to determine whether to automatically perform one or more additional adjustments based in part upon the one or more additional cooling requirements.

18. The computer-implemented method of claim 16, wherein the plurality of heat-generating components includes at least one server, switch, router, network interface controller, tray, system on chip, or compute resource.

19. The computer-implemented method of claim 16, wherein the tags attached to the heat-generating components include at least radio frequency identification (RFID) tags, near-field communications (NFC) tags, QR codes, bar codes, identification stickers, physical connections to memory, or Bluetooth transmitters.

20. The computer-implemented method of claim 16, further comprising:
determining, based in part on one or more additional requirements of the heat-generating component, one or more additional adjustments to be made with respect to at least one source of air cooling or power.

21. The computer-implemented method of claim 16, further comprising:
determining, from information associated with the tag, at least one of expected flow rate, required cooling capacity, expected pressure, minimum or maximum temperature of the heat-generating component, liquid viscosity requirements, cooling loop configuration, maintenance schedule or alerts, cooling efficiency metrics, pressure drops, heat generation profile, and emergency shutdown procedures.
